(19) United States
(12) Patent Application Publication
(10) Pub. No.: US 2011/0263133 A1
(43) Pub. Date: Oct. 27, 2011

(54) SEMICONDUCTOR DEVICE MANUFACTURING APPARATUS AND SEMICONDUCTOR DEVICE MANUFACTURING METHOD

(75) Inventors: Satoru Hara, Fujisawa-shi (JP); Shingo Tamai, Yokohama-shi (JP); Akihiro Shigeyama, Yokohama-shi (JP); Michio Ogawa, Yokohama-shi (JP); Hitoshi Aoyagi, Hiratsuka-shi (JP); Hiroyuki Tanaka, Fujisawa-shi (JP); Yasuo Tane, Yokkaichi-shi (JP); Yukio Katamura, Mie-gun (JP)

(73) Assignees: Kabushiki Kaisha Toshiba, Tokyo (JP); SHIBAURA MECHATRONICS CORPORATION, Yokohama-shi (JP)

(21) Appl. No.: 13/092,523

(22) Filed: Apr. 22, 2011

(30) Foreign Application Priority Data
Apr. 23, 2010 (JP) JP2010-099983

(51) Int. Cl. H01L 21/30; B05C 5/00

(52) U.S. Cl. 438/758; 118/620; 257/E21.214

(57) ABSTRACT

A semiconductor device manufacturing apparatus includes: an accommodation section accommodating an application object; an irradiation section irradiating the application object taken out from the accommodation section with ultraviolet light; an application section including a stage allowing the application object to be placed thereon and an application head discharging a plurality of droplets of an adhesive to the application object placed on the stage, the application section applying the adhesive through the application head to the application object which is irradiated by ultraviolet light through the irradiation section and is placed on the stage; a drying section drying the adhesive applied on the application object with heat; and a transport section including a hand supporting the application object, the transport section which is capable of transporting the application object accommodated in the accommodation section to the irradiation section, the application section, and the drying section.

### BACKGROUND OF THE INVENTION

1. Technical Field

The present invention relates to a semiconductor device manufacturing apparatus and a semiconductor device manufacturing method.

2. Background Art

In a typical semiconductor device manufacturing process, a semiconductor wafer is mounted on a dicing tape with an adhesive tape (also called a DAF material) interposed therebetween. The mounted semiconductor wafer is singulated by blade dicing to manufacture a plurality of semiconductor chips (see Patent Publication 1: JP2008-270282A).

To mount the semiconductor wafer on the dicing tape, first, the surface of the semiconductor wafer opposite to the element formation surface is ground, and the ground surface is attached to an adhesive sheet. The semiconductor wafer is then mounted on the dicing tape with the attached adhesive sheet interposed therebetween. After dicing, UV irradiation is performed for the dicing tape from the rear surface side of the semiconductor wafer to reduce the adhesion of the dicing tape to the adhesive sheet for the purpose of pick up at a post-process of detaching the semiconductor chips from the dicing tape.

Patent Publication 1 discloses a technique of applying an adhesive directly to the surface of the semiconductor wafer opposite to the element formation surface to form an coating film of the adhesive instead of the adhesive sheet. This makes it possible to manufacture semiconductor devices of high quality at low cost.

### SUMMARY OF THE INVENTION

However, Patent Publication 1 does not disclose a specific configuration of an apparatus directly applying the adhesive to the surface of the semiconductor wafer opposite to the element formation surface.

The present invention was made in the light of the above description, and an object of the present invention is to provide a semiconductor device manufacturing apparatus and a semiconductor device manufacturing method which are capable of forming a coating film of an adhesive on an application object to a desired film thickness.

A semiconductor device manufacturing apparatus according to a first aspect of the present invention includes: an accommodation section accommodating an application object; an irradiation section irradiating the application object taken out from the accommodation section with ultraviolet light; an application section including a stage allowing the application object to be placed thereon and an application head discharging a plurality of droplets of an adhesive to the application object placed on the stage, the application section applying the adhesive through the application head to the application object which is irradiated by ultraviolet light through the irradiation section and is placed on the stage; a drying section drying the adhesive applied on the application object with heat; and a transport section including a hand supporting the application object, the transport section which is capable of transporting the application object accommodated in the accommodation section to the irradiation section, the application section, and the drying section.

A semiconductor device manufacturing method according to a second aspect of the present invention includes: taking out an application object from an accommodation section configured to accommodate the application object using a transport section configured to transport the application object with a hand supporting the application object; irradiating the application object with ultraviolet light using an irradiation section configured to project ultraviolet light to the application object taken from the accommodation section with the hand; transporting the application object irradiated by the ultraviolet light onto the stage using the transport section; applying adhesive to the application object transported on the stage using an application head configured to discharge a plurality of droplets of the adhesive; transporting the application object with the adhesive applied thereto to a drying section configured to dry the application object with heat using the transport section; and drying the adhesive applied to the application object using the drying section.

According to the aspects of the present invention, it is possible to form a coating film of an adhesive on an application object to a desired thickness.

### BRIEF DESCRIPTION OF THE DRAWINGS

FIG. 1 is a plan view illustrating a schematic configuration of a semiconductor device manufacturing apparatus according to an embodiment.

FIG. 2 is a schematic view illustrating an accommodation section provided for the manufacturing apparatus of FIG. 1.

FIG. 3 is a plan view illustrating a support plate provided for the accommodation section of FIG. 2.

FIG. 4 is a plan view illustrating a hand of a transport section provided for the manufacturing apparatus of FIG. 1.

FIG. 5 is a cross-sectional view taken along a line F5-F5 of FIG. 4.

FIG. 6 is an explanatory view for explaining an action that the hand of FIG. 4 performs to take out a wafer from the accommodation section.

FIG. 7 is a schematic view illustrating an alignment section and a drying section provided for the manufacturing apparatus of FIG. 1.

FIG. 8 is a plan view illustrating a centering unit provided for the alignment section of FIG. 7.

FIG. 9 is a plan view illustrating a pre-alignment unit provided for the alignment section of FIG. 7.

FIG. 10 is an explanatory view for explaining alignment of a pre-diced wafer using a notch.

FIG. 11 is an explanatory view for explaining alignment of a diced wafer using a notch.

FIG. 12 is a schematic view illustrating an irradiation section provided for the manufacturing apparatus of FIG. 1.

FIG. 13 is an explanatory diagram for explaining a relation between operating time and illuminance of a UV lamp provided for the irradiation section of FIG. 12.

FIG. 14 is a schematic view illustrating a stage of an application section provided for the manufacturing apparatus of FIG. 1.

FIG. 15 is a plan view illustrating positions of lift pins provided for the stage of FIG. 14.

FIG. 16 is a plan view illustrating positions of suction holes provided for the stage of FIG. 14.

FIG. 17 is a schematic view illustrating a discharge checking portion constituting a discharge stabilization unit of the application section provided for the manufacturing apparatus of FIG. 1.

FIG. 18 is a plan view illustrating the discharge checking portion of FIG. 17.

FIG. 19 is a schematic view illustrating a cleaning moisturizing portion constituting the discharge stabilization unit of the application section provided for the manufacturing apparatus of FIG. 1.

FIG. 20 is a plan view illustrating the cleaning moisturizing portion of FIG. 19.

FIG. 21 is a schematic view illustrating a discharge amount checking portion constituting the discharge stabilizing unit of the application section provided for the manufacturing apparatus of FIG. 1.

FIG. 22 is a plan view illustrating the discharge amount checking portion of FIG. 21.

FIG. 23 is a schematic view illustrating a cleaning unit of the application section provided for the manufacturing apparatus of FIG. 1.

FIG. 24 is a plan view illustrating a heater plate provided for the drying section of FIG. 7.

FIG. 25 is a flowchart illustrating a flow of a manufacturing process performed by the manufacturing apparatus of FIG. 1.

### DETAILED DESCRIPTION OF THE EMBODIMENTS

A description is given of an embodiment of the present invention with reference to the drawings.

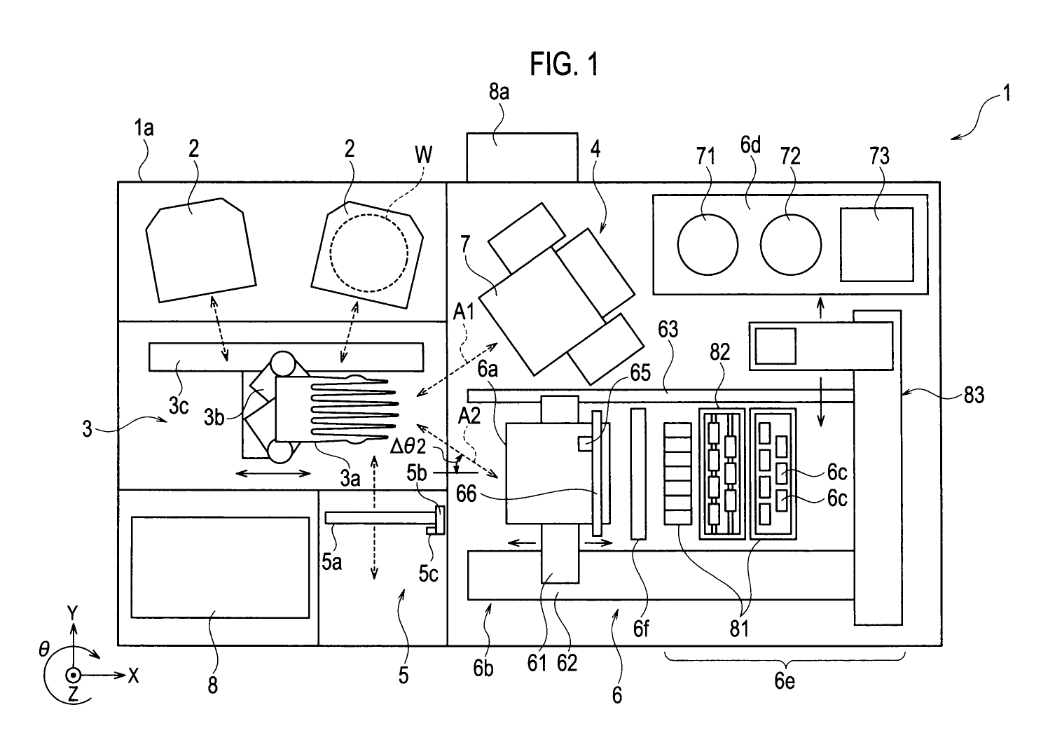

As illustrated in FIG. 1, a semiconductor device manufacturing apparatus 1 according to the embodiment of the present invention includes: a plurality of accommodation sections 2 accommodating wafers W as application objects (or processing objects); a transport section 3 transporting the wafers W; an alignment section 4 performing pre-alignment; an irradiation section 5 performing irradiation of ultraviolet light; an application section 6 applying an adhesive to the surface of each wafer W; a drying section 7 performing pre-drying; and a controller 8 controlling each section.

The aforementioned sections are arranged on a rack 1a of the manufacturing apparatus 1 so as to surround the transport section 3. As illustrated in FIG. 1, the transport section 3 is provided at the center of the left side of the rack 1a, and the accommodation sections 2 are provided above the transport section 3. The alignment section 4 and drying section 7 are provided to the upper right of the transport section 3, and the irradiation section 5 is provided under the transport section 3. The application section 6 is provided to the lower right of the transport section 3. The adhesive applied to the wafer W is provided to be used for bonding to mount chips obtained by singulating the wafer W. After the coating film of the adhesive is formed on the wafer W by the semiconductor device manufacturing apparatus 1, as described in the conventional art, the wafer W is cut by dicing or the like to be singulated into chips. Thereafter, each chip is taken out for die bonding or the like and then mounted with the adhesive applied by the semiconductor device manufacturing apparatus 1 directly on a substrate or with another chip or the like interposed therebetween.

Each accommodation section 2 is a wafer cartridge for inserting or ejecting the wafers W. The accommodation sections 2 are formed so as to be attached and detached from the rack 1a of the manufacturing apparatus 1. In the embodiment of the present invention, there are two accommodation sections 2, for example. One of the accommodation sections 2 is used for supplying wafers W, and the other is used for exporting the wafers W.

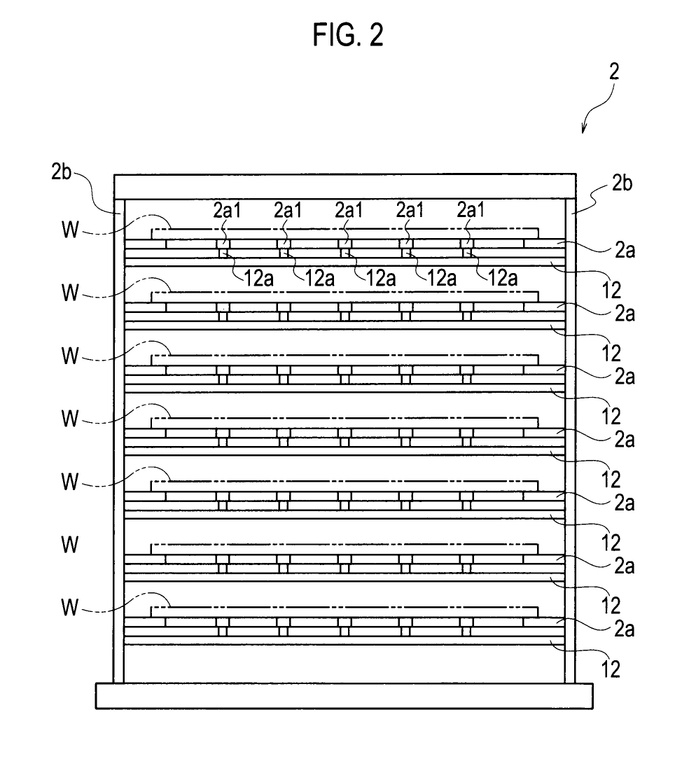

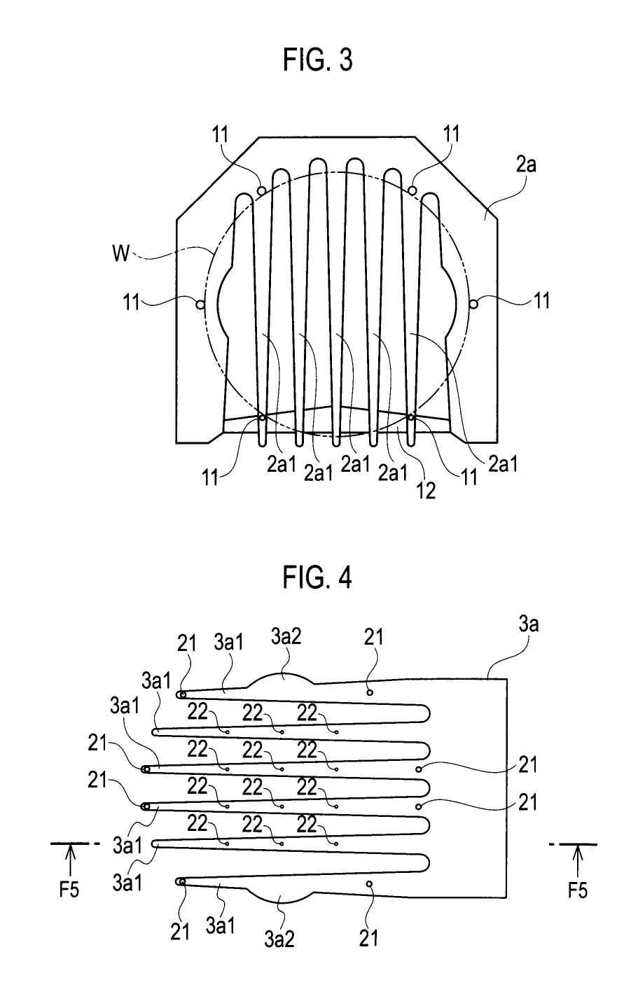

As illustrated in FIGS. 2 and 3, each of the accommodation sections 2 includes: a plurality of support plates 2a supporting individual wafers W; and a pair of holders 2b holding the support plates 2a stacked in a multilayer manner (see FIG. 2). Each of the holders 2b has a plate or columnar shape, for example.

Each of the support plates 2a has a comb shape having a plurality of support portions 2a1 (five in the embodiment) supporting wafers W and supports the lower surface of a placed wafer W. The support plate 2a is provided with a plurality of hold pins 11 (see FIG. 3). Under the tips of the support portions 2a1 constituting the comb teeth of the support plate 2a, a reinforcement member 12 reinforcing the support portions 2a1 is extended across the direction that the support portions 2a1 extend. The reinforcement member 12 includes a plurality of joint supports 12a (see FIG. 2) and supports the individual tips of the support portions 2a1 with the joint supports 12a interposed therebetween. The support plates 2a are provided at predetermined intervals.

The hold pins 11 are arranged in a circle according to the outer shape of the wafer W and configured to restrict movement of the wafer W placed on each support plate 2a in the in-plane direction. The tip of each of the hold pins 11 is tapered. Accordingly, even if the wafer W is supplied to the support plate 2a with the center thereof a little deviated from the center of the circle of the hold pins 11 arranged, a peripheral part of the wafer W comes into contact with tapered portions of some tips of the hold pins 11 and are then horizontally pressed as the wafer W is going down through the hold pins 11. The wafer W is thus positioned at the center of the circle of the hold pins 11. The wafer W is placed on a circular area of the support plate 2a surrounded by the hold pins 11 and is held with the horizontal movement restricted by the hold pins 11. In the example of FIG. 3, six hold pins 11 are arranged in a circle.

As illustrated in FIG. 1, the transport section 3 includes a hand 3a, an arm 3b, and an arm movement driving unit 3c. The hand 3a is movable while holding the wafer W. The arm 3 is capable of expanding and contracting, going up and down, and rotating in the in-plane direction while supporting the hand 3a. The arm movement driving unit 3c supports the arm 3b and moves the same in an X-axis direction. The transport section 3 performs exchange of the wafer W among the accommodation sections 2, the alignment section 4, the irradiation section 5, the application section 6, and the drying section 7.

As illustrated in FIG. 4, the hand 3a has a comb teeth shape including a plurality of support portions 3a1 (six in the embodiment) supporting the wafer W and supports the lower surface of the placed wafer W. The support portions 3a1 constitute comb teeth which are capable of entering gullets of the support portions 2a1 constituting the comb teeth of the support plate 2a (see FIG. 3) provided for the accommodation section 2 (hereinafter, this state is referred to as “interdigitated”). Each of the support portions 3a1 at the both sides of the hand 3a is provided with a wide portion 3a2 having a shape according to the outer shape of the wafer W placed on the hand 3a. The hand 3a is provided with a plurality of hold pins 21 and a plurality of suction holes 22.

The hold pins 21 are arranged in a circle according to the outer shape of the wafer W and restrict movement of the wafer W placed on the hand 3a in the in-plane direction. To be more specific, the hold pins 21 are arranged at intervals along the circumference of a circle having a diameter about several millimeters larger than the diameter of the wafer W. Each hold pin 21 has a tapered tip. Accordingly, even when the wafer W is received by the hand 3a with the center a little deviated from the center of the circle of the hold pins 21, a peripheral part of the wafer W comes into contact with the tapered portions of some tips of the hold pins 21 and are horizontally pressed as the wafer W goes down through the hold pins 11. The wafer W is thus positioned in the circle of the hold pins 21. As described above, the wafer W is placed in the circular area surrounded by the hold pins 21 on the hand 3a, and the hold pins 21 limit the movement of the wafer W in the in-plane direction. In the example of FIG. 4, eight hold pins 21 are arranged in a circle.

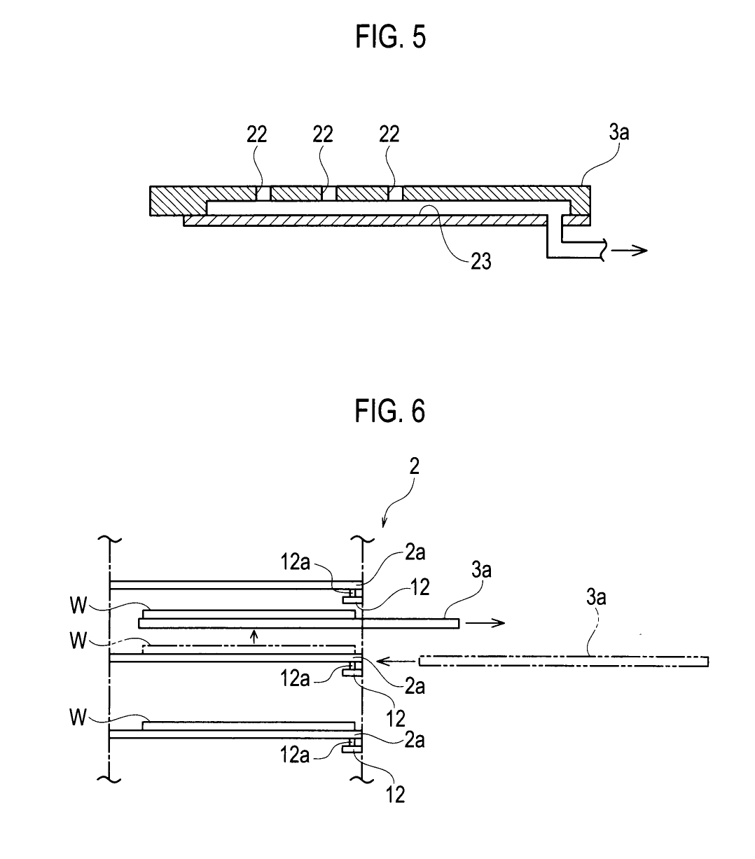

The suction holes 22 are provided so as to allow the wafer W to be well sucked to around the center of the comb teeth of the hand 3a. As illustrated in FIG. 5, the suction holes 22 communicate with a suction channel 23 formed within the hand 3a. The suction channel 23 is connected through piping such as tubes or pipes to a suction unit (not illustrated) such as a suction pump. The wafer W sticks due to suction through the suction holes 22 to be held while the movement thereof in the in-plane direction is restricted by the hold pins 21. The wafer W is attracted using a vacuum chuck, a local Bernoulli chuck, or the like, for example.

As illustrated in FIG. 1, the arm 3b is configured so as to extend and contract, move up and down, and horizontally rotate. Moreover, the arm 3b is further configured to move in the X-axis direction by the arm movement driving portion 3c. The arm 3b extends and contracts to advance and retract the hand 3a. The arm 3b is electrically connected to the controller 8, and the driving of extension and contraction, up and down movement, and horizontal rotation is controlled by the controller 8.

The arm movement driving portion 3c is a moving mechanism guiding and moving the arm 3b in the X-axis direction and is provided on the rack 1a. The arm movement driving portion 3c is electrically connected to the controller 8, and the driving thereof is controlled by the controller 8. The arm movement driving portion 3c is composed of a feed screw-type driving unit using a servomotor as a driving source, a linear motor-type driving unit using a linear motor as a driving source, or the like, for example.

As illustrated in FIG. 6, the support portions 3a1 constituting the comb teeth of the hand 3a are inserted into depressions between the support portions 2a1 constituting the comb teeth of each support plate 2a provided for the accommodation section 2 to be interdigitated with the support portions 2a1 of the support plate 2a through the extension operation of the arm 3b. Next, the hand 3a moves upward through the operation of the arm 3b and comes into contact with the lower surface of the wafer W placed on the support plate 2a. At this time, the hand 3a restricts the horizontal movement of the wafer W with the hold pins 21 and moreover attracts and holds the wafer W through the suction holes 22. The hand 3a moves further upward by the operation of the arm 3b. After the movement, the hand 3a retracts back to take the wafer W out of the accommodation section 2 and then supplies the wafer W into the alignment section 4. Eventually, the hand 3a holding the wafer W moves in the X-axis direction together with the arm 3b and transfers the wafer W to the alignment section 4. The export of the wafer W is performed in the reverse procedure to the supply operation.

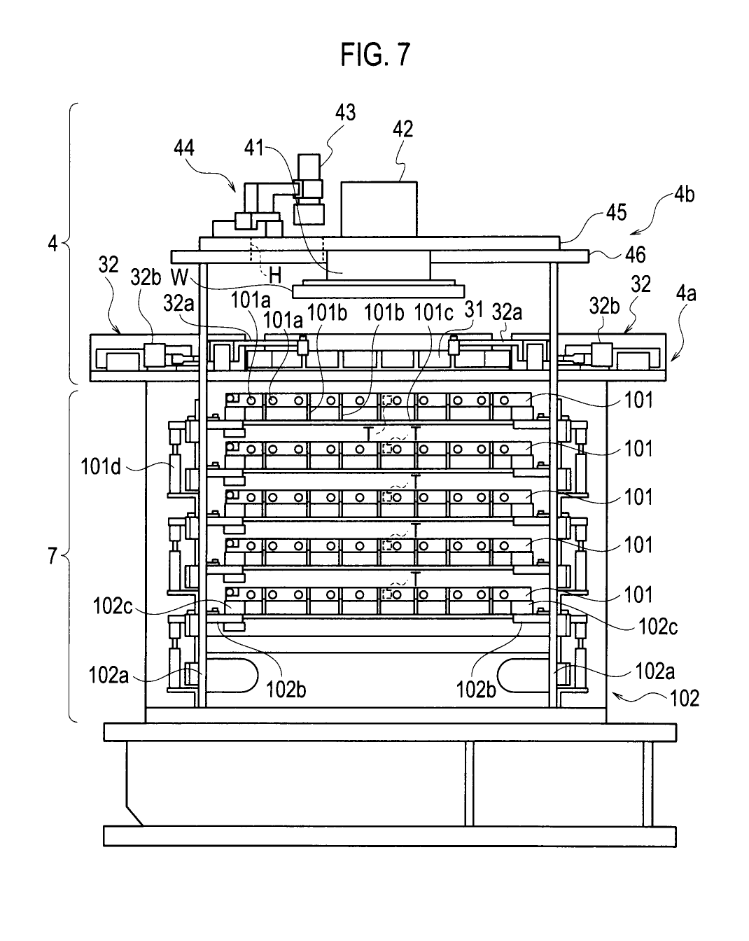

As illustrated in FIG. 7, the alignment section 4 includes: a centering unit 4a and a pre-alignment unit 4b. The centering unit 4a performs alignment of the hand 3a of the transport section 3 with the wafer W on the hand 3a in the in-plane direction (the X-Y direction). The pre-alignment unit 4b performs alignment in the rotation direction (the θ direction). The alignment section 4 is provided on the drying section 7.

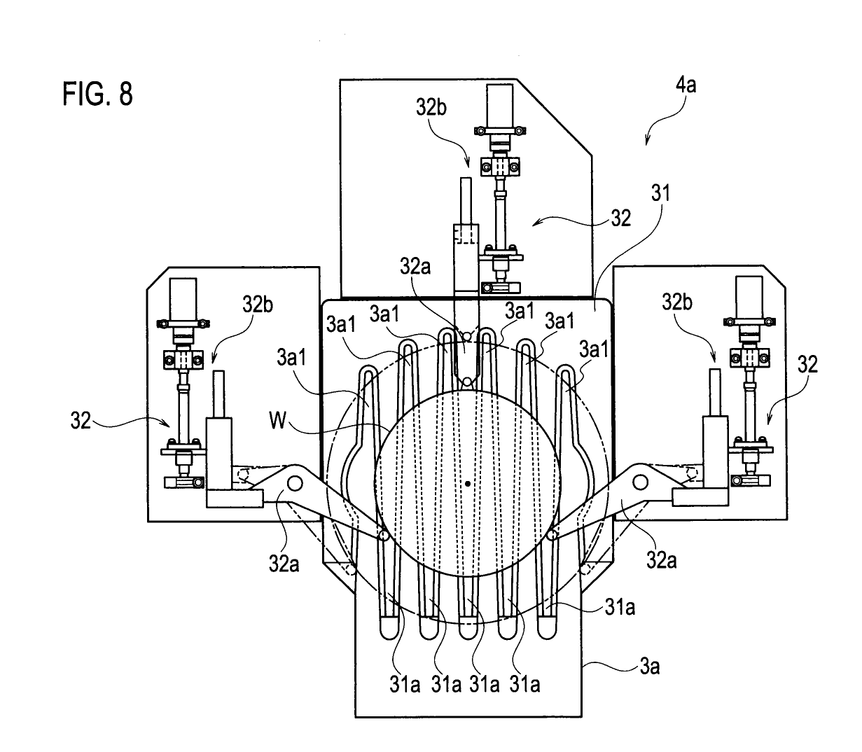

As illustrated in FIGS. 7 and 8, the centering unit 4a includes a support table 31 supporting the wafer W and a plurality of press portions 32 pressing the wafer W supported on the support table 31 in the in-plane direction for centering. In this embodiment, the number of the press portions 32 is three.

The centering unit 4a is a mechanism to align the center of the wafer W with the center of the hand 3a (which corresponds to the center of the circle of the hold pins 21). The wafer W is positioned with respect to the hand 3a by the hold pins 21. Herein, the diameter of the circle inscribed in the eight hold pins 21 is larger than that of the wafer W. Accordingly, the wafer W is positioned at low accuracy including an error equal to the difference in size between the wafer W and the circle of the hold pins 21. The centering unit 4a is therefore configured to perform more accurate positioning than the hold pins 21. The center of the hand 3a serves as a referential position at subsequent processes (the referential position for application). It is therefore necessary to align the center of the wafer W with the center of the hand 3a with high accuracy. The centering unit 4a performs mechanical centering so as not to damage the edge of the wafer W and protective film on the wafer W.

The support table 31 includes a plurality of support portions 31a (five in the embodiment) constituting comb teeth having such a shape that the support portions 3a1 constituting the comb teeth of the hand 3a fit into the depressions of the support portions 31a c (hereinafter, this state is referred to as “interdigitated”) (see FIG. 8). To be specific, in the support table 31, recesses are formed so as to fit to the support portions 3a1 constituting the comb teeth of the hand 3a. The upper surface of the support table 31 constitutes the support portions 31a supporting the wafer W. The hand 3a enters between the support portions 31a constituting the comb teeth of the support table 31 to exchange the wafer W. At this time, the position of the hand 3a positioned with respect to the support table 31 is previously adjusted to such a position that the center of the wafer W already subjected to the centering on the support table 31 coincides with the center of the hand 3a. Accordingly, the center of the hand 3a can be aligned with the center of the wafer W by centering the wafer W on the support table 31.

Each of the press portions 32 includes a lever 32a coming into contact with the edge of the wafer W and a movement driving portion 32b moving the lever 32a in the in-plane direction.

The lever 32a includes a pin (not illustrated) protruding downward from the underside of the end of the lever 32a. The lever 32a is moved by the movement driving portion 32b to bring the pin into contact with the wafer W and press the wafer W in the in-plane direction. Each support portion 31a constituting the comb teeth of the support table 31 is provided with a notch (not illustrated) allowing the pin of each lever 32a to move. The lever 32a is formed so that the stop positions can be changed according to the size of the wafer W to be subjected to centering (for example, 8 and 12 inches). The stop positions are set so that small gap is formed between the pin of each lever 32a and the circumference of the wafer W. This can prevent the wafer W from getting caught by the three levers 32a and damaged (split or cracked). This gap is enough smaller than the difference between the diameter of the circle inscribed in the hold pins 21 of the hand 3a and the diameter of the wafer W.

The movement driving portion 32b is electrically connected to the controller 8, and the driving thereof is controlled by the controller 8. The movement driving portion 32b is composed of a feed screw-type driving unit using a servomotor as a driving source or the like or an air cylinder, for example. In the embodiment of the present invention, the movement driving portion 32b is composed of a feed screw mechanism. Using the feed screw mechanism, the feed amount can be easily adjusted through the rotational amount of the servomotor. Accordingly, it is possible to facilitate adjusting the stopping positions of the levers 32a and adjusting the centering position of the wafer W.

As described above, the centering unit 4a presses the pins of the levers 32a of the press portions 32 against the circumferential edge of the wafer W on the support table 31 in the three directions. By being pressed by the pins of the lever parts 32a, the wafer W is moved in the in-plane direction for alignment of the center of the hand 3a with the center of the wafer W (centering).

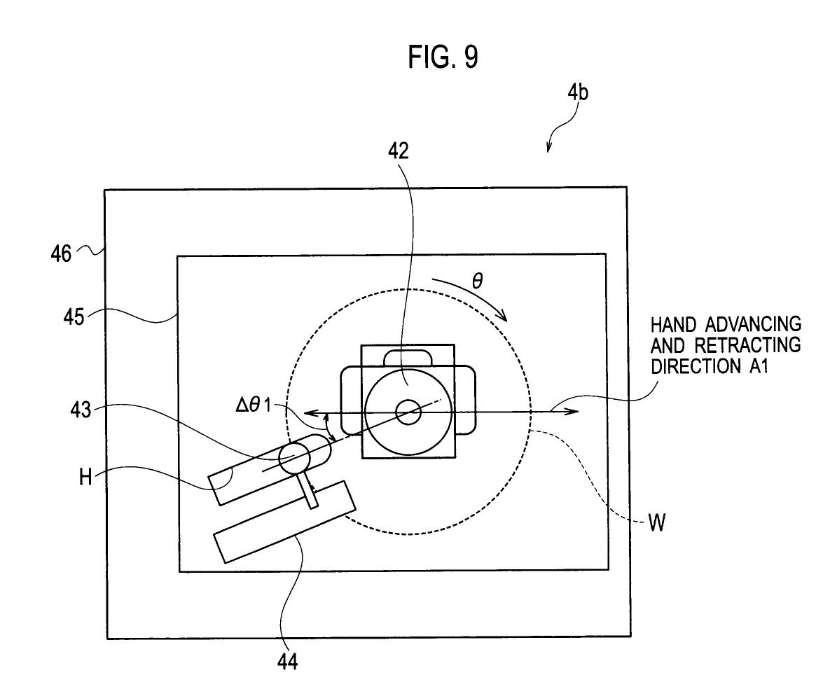

As illustrated in FIGS. 7 and 9, the pre-alignment unit 4b includes a holding portion 41, a rotation driving portion 42, an imaging portion 43, and a movement driving portion 44. The holding portion 41 sucks and holds the wafer W on the bottom surface thereof. The rotation driving portion 42 rotates the holding portion 41 in the in-plane direction. The imaging portion 43 takes an image of the peripheral part of the wafer W held by the holding portion 41 from above. The movement driving portion 44 moves the imaging portion 43 in the radial direction of the wafer W. Herein, the peripheral part of the wafer W refers to a region including an edge in which a later-described notch N is formed.

The holding portion 41 is a disk-shaped stage including a vacuum suction mechanism. The holding portion 41 sucks and holds the wafer W on the bottom surface and receives the wafer W from the hand 3a of the transport section 3. The in-plane size of the holding portion 41 is smaller than the in-plane size of the wafer W so that the imaging portion 43 can take an image of the peripheral part of the wafer W. When the holding portion 41 holds the wafer W, the peripheral part of the wafer W protrudes from the circumference of the holding portion 41 (the circumference of the stage), and the image thereof can be taken. The holding portion 41 is formed so as to be attached to and detached from the rotation driving portion 42 and can be replaced according to the size of the wafer W.

The rotation driving portion 42 is a rotation mechanism supporting and rotating the holding portion 41 in a θ direction (see FIG. 9) and is provided above the holding portion 41. The rotation driving portion 42 is electrically connected to the controller 8, and the driving thereof is controlled by the controller 8.

The imaging portion 43 is provided so as to take images of the peripheral part of the holding portion 41 from above. The imaging portion 43 is electrically connected to the controller 8, and the driving thereof is controlled by the controller 8. The imaging portion 43 is composed of a CCD camera or the like, for example. Plates 45 and 46 placed under the imaging portion 43 are provided with openings H serving as a window for shooting images so that the imaging portion 43 can take an image of the peripheral part of the wafer W. The openings H are obliquely elongated in a plan view (see FIG. 9), and the imaging portion 43 takes an image of the peripheral part of the wafer W through the openings H.

The openings H are elongated because the position of the imaging portion 43 can be changed according to the size of the wafer W to be handled (8 or 12 inches). Accordingly, the openings H are elongated in the direction that the imaging portion 43 moves (in the radial direction of the holding portion 41). Moreover, the opening H is obliquely formed because the notch N of the wafer W is detected at a position tilted by a predetermined angle with respect to the direction that the hand 3a of the transport section 3 advances and retracts. In other words, the hand 3a advances and retracts in an oblique direction (indicated by an arrow A2 of FIG. 1) with respect to the X-axis direction that a stage 6a of the application section 6 (described later) moves. The wafer W is positioned at a predetermined angle with respect to the hand 3a in the rotation direction so that the notch N of the wafer W is directed in the direction that the stage 6a moves (in the X-axis direction) when the wafer W is transferred from the hand 3a to the stage 6a. Accordingly, an angle Δθ1 between the direction that the hand 3a advances to and retracts from the pre-alignment unit 4b (indicated by the arrow A1 of FIGS. 1 and 9) and the straight line connecting the rotational center of the holding portion 41 and the center of the visual field of the imaging portion 43 is set equal to an angle Δθ2 between the direction that the hand 3a advances to and retracts from the stage 6a of the application section 6 (indicated by an arrow A2 of FIG. 1) and the direction that the stage 6a moves (the X-axis direction). The notch N of the wafer W is positioned at the angle Δθ1 (˜Δθ2) with respect to the hand 3a.

The movement driving portion 44 is a moving mechanism moving the imaging portion 43 according to the size of the wafer W to the shooting position where the imaging portion 43 can take an image of the peripheral part of the wafer W. The movement driving portion 44 is electrically connected to the controller 8, and the driving thereof is controlled by the controller 8. At this time, the imaging portion 43 is moved inside close to the rotational center of the holding portion 41 when the wafer W is small as 8 inch and is moved outside far from the rotational center of the holding portion 41 when the wafer W is large as 12 inch. The movement driving portion 44 is composed of a feed screw-type driving unit using a servomotor as a driving source or an air cylinder, for example.

As described above, the pre-alignment unit 4b sucks and holds the wafer W on the bottom surface of the holding portion 41 and moves the imaging portion 43 to the shooting position by the movement driving portion 44. The pre-alignment unit 4b then rotates the holding portion 41 by the rotation driving section 42 while taking images of the peripheral part of the rotating wafer W through the openings H of the plate 45 and 46 by the imaging portion 43. To be more specific, the rotation driving portion 42 rotates the holding portion 41 at a set rotation speed. While the holding portion 41 is rotating, the imaging portion 43 takes images of the peripheral part of the wafer W at predetermined shooting times based on the control of the controller 8. The shooting times are set so that an image taken by the imaging portion 43 overlaps an image to be taken next. For example, in the case where the imaging portion 43 has such a field of view that an arc of 20 degrees in the circumference of the wafer W can be imaged with one shooting, the imaging portion 43 is configured to take an image each time the holding portion 41 rotates 15 degrees. The holding portion 41 may be stopped when the imaging portion 43 takes each image. Alternatively, the imaging portion 43 may take an image at each set time while the holding portion 41 is continuously rotated (at each 15 degrees, for example).

In the surface of the wafer W, a plurality of chips (semiconductor elements) are arranged in a lattice. This surface is an element formation surface. To the element formation surface, protective tape is attached. On the other hand, the rear surface of the wafer W is polished with a grinder or the like, and this surface is an application surface to which an adhesive is to be applied.

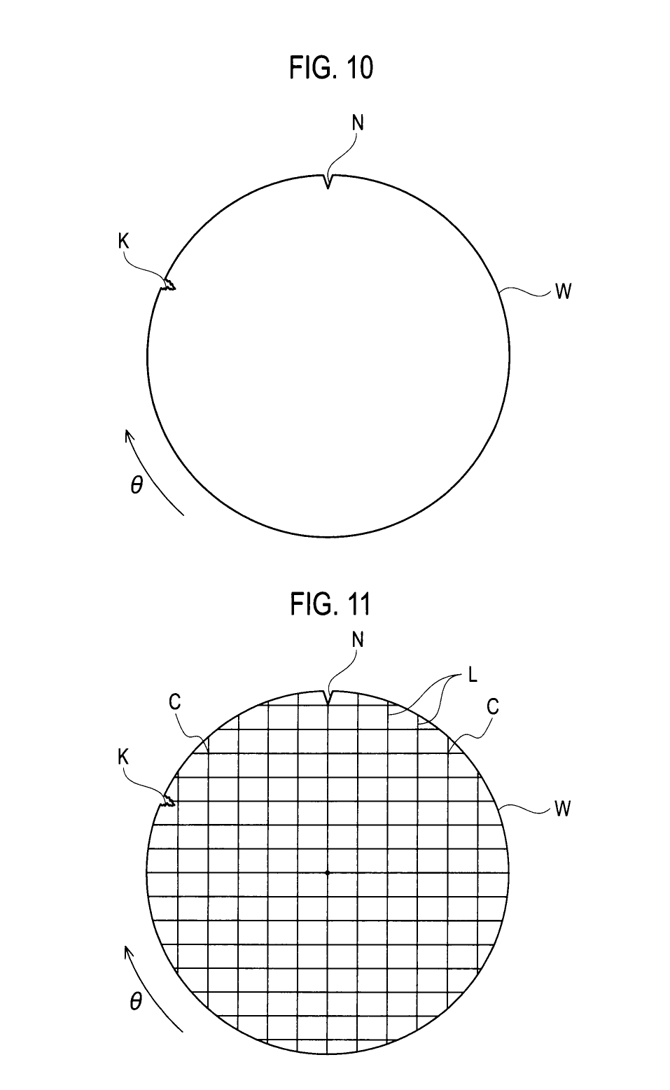

FIGS. 10 and 11 illustrate the rear surface (application surface) of the wafer W. FIG. 10 illustrates a wafer not subjected to pre-dicing (hereinafter, referred to as an undiced wafer). FIG. 11 illustrates a wafer subjected to pre-dicing (hereinafter, referred to as a pre-diced wafer). Herein, the pre-dicing refers to cutting to a predetermined depth. The pre-diced wafer is completely cut later to be singulated at a post-process. In FIG. 11, dicing grooves in a lattice are formed in the rear surface (application surface) of the wafer by pre-dicing.

As described above, as illustrated in FIG. 10, each wafer W is typically provided with the notch N in the edge of the wafer W for alignment. However, in some cases, in the edge of the wafer W, there is a crack K generated during the transport process or the like other than the notch N. If the crack K is mistaken as the notch N, accurate alignment cannot be performed.

Accordingly, the pre-alignment unit 4b performs image processing for the taken images and compares an image of the crack part with an image of a reference notch previously registered as a reference. Specifically, the pre-alignment unit 4b performs pattern matching of the image of crack part and the image of the reference notch to determine whether the crack part corresponds to the notch N. When the crack part matches the reference notch, the crack part is determined to be the Notch N. When the crack part does not match the reference notch, the crack part is determined to be the crack K. This can prevent that the crack K of the wafer W is mistaken as the notch N.

To be specific, the pre-alignment unit 4b includes a not-illustrated image processing computing portion. The pre-alignment unit 4b determines whether there is a pattern matching the previously stored image of the reference notch through the image processing computing portion each time the imaging portion 43 takes an image of the peripheral part of the wafer W. If there is a pattern matching the previously stored image of the reference notch, the pre-alignment unit 4b calculates a position of the pattern (notch N) in the peripheral part of the wafer W (the distance from the position where the notch N is supposed to be positioned in the rotation direction (θ direction)). For example, when the notch N is supposed to be positioned at the center of the field of view of the imaging portion 43, the pre-alignment unit 4b calculates the distance of the notch N from the center of the field of view in the θ direction based on the radius of the wafer W and gaps between the notch N and the center of the field of view (the central position of the image) in the X and Y directions in the image.

The image processing is performed each time that the imaging portion 43 takes an image in the above. However, the image processing may be performed for each image after the image portion 43 finishes taking all the images of the peripheral part of the wafer W. However, it is efficient to perform the image processing each time that the imaging portion 43 takes an image because taking images can be stopped when the notch N is detected. Moreover, the image processing computing part is provided for the pre-alignment unit 4b, but the function thereof may be provided for the controller 8.

In such a manner, the notch N is recognized, and the position of the notch N and the amount of correction thereof from a radius of the wafer W in the θ direction are calculated. The position of the wafer W in the θ direction is corrected based on the calculated amount of correction. The position is corrected by the rotation driving portion 42 under the control of the controller 8 when the wafer W is transferred from the holding portion 41 to the hand 3a of the transport section 3. The controller 8 drives the rotation driving portion 42 with the calculated amount of correction, aligns the position of the notch N of the wafer W with the center of the field of view, and then transfers the wafer W to the hand 3a of the transport section 3. The notch N of the wafer W is thus directed in the direction that the stage 6a of the later-described application section 6 moves (in the X-axis direction) when the wafer W is transferred from the hand 3a of the transport section 3 to the stage 6a.

In the case of an undiced wafer W, the wafer W is unnecessary to be positioned so that the notch N is directed in the direction that the stage 6a moves in some cases. In the case of forming a circular adhesive film only inside the region where the notch N is formed in the wafer W, for example, the notch N does not need to be directed to the direction that the stage 6a moves. In such a case, information on whether the wafer W supplied from one of the accommodation sections 2 is undiced or pre-diced or information on whether the pre-alignment is necessary is previously stored in a storage (a storage provided for the controller 8, for example). Based on the stored information, the controller 8 determines whether to execute the pre-alignment by the pre-alignment unit 4b. The pre-alignment is executed only when the pre-alignment is necessary. Moreover, even in the case of an undiced wafer W, when the adhesive film is to be formed in a circle in the region where the notch N is formed excepting the notch N, the pre-alignment should be executed based on previously stored information that the pre-alignment is necessary.

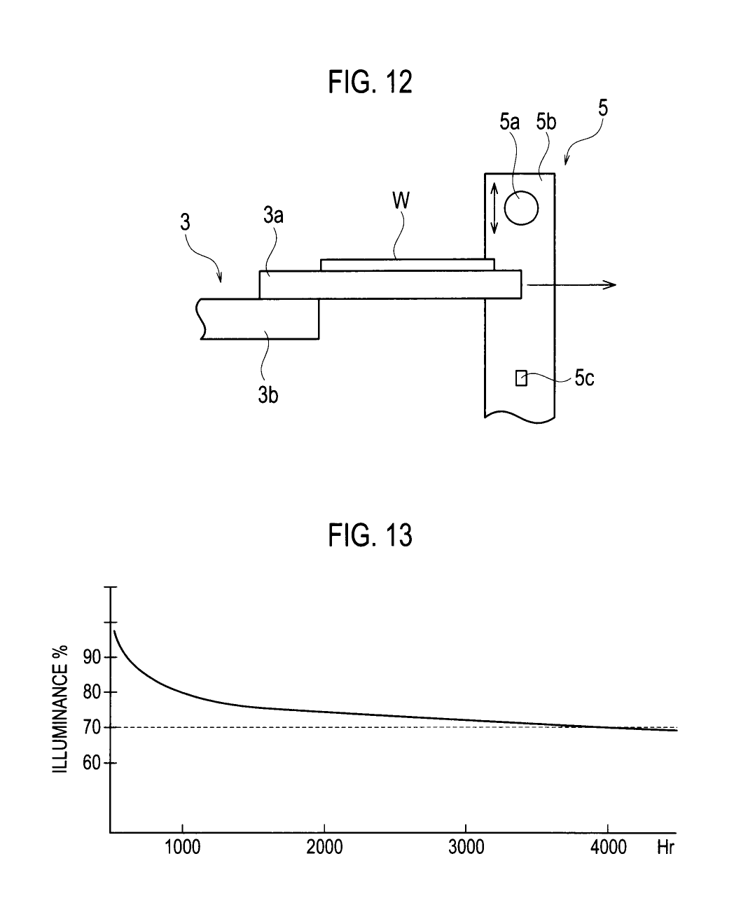

As illustrated in FIG. 12, the irradiation section 5 includes a UV lamp 5a, a lamp movement driving unit 5b, and a sensor 5c. The UV lamp 5a generates UV light (ultraviolet light). The lamp movement driving unit 5b moves the UV lamp 5a in the Z-axis direction. The sensor 5c is a detector detecting an amount of UV light (an amount of ultraviolet light). The irradiation section 5 is provided within a box-shaped UV housing (not illustrated) including inlet/outlet ports for the wafer W. The UV housing includes an atmosphere of gas, such as nitrogen or oxygen, at positive pressure.

The lamp movement driving unit 5b is a moving mechanism moving the UV lamp 5a in the Z-axis direction (in a direction that the UV lamp 5a approaches and separates from the wafer W) to adjust the distance (gap) between the wafer W and UV lamp 5a. The lamp movement driving unit 5b is composed of a feed screw-type driving unit using a servomotor as a driving source, for example.

In such a manner, the irradiation section 5 irradiates the rear surface of the wafer W (the application surface to which the adhesive is applied) with UV light for surface modification. The adhesive can be therefore stably stick to the application surface of the wafer W, thus improving the adhesion between the application surface of the wafer W and the adhesive.

In order to ensure a predetermined integrated amount of light necessary for surface modification, the wafer W supported by the hand 3a of the transport section 3 is reciprocated by the operation of the arm 3b with respect to the one UV lamp 5a. This makes it possible to obtain the same integrated amount of light as that by irradiation performed when the wafer W is passed one way by two UV lamps 5a arranged in parallel.

UV light projected from the UV lamp 5a attenuates with time as illustrated in FIG. 13. Accordingly, in order for the application surface (rear surface) of the wafer W to stably provide good adhesion to the adhesive, it is necessary to keep the amount of UV light projected on the wafer W constant at a predetermined amount.

The irradiation section 5 controls various conditions so that the amount of UV light irradiating the wafer W is constant at a predetermined amount according to the amount of UV light detected by the sensor 5c. For example, in the case where the illuminance of the UV lamp 5a attenuates to about 70% when the UV lamp 5a reaches an operating life of 4000 hours as illustrated in FIG. 13, various conditions are controlled so that the illuminance to the wafer W is maintained at 70% corresponding to the end of the life of the lamp 5a to keep the amount of UV light constant (adjustment section). Specifically, when the amount of UV light detected by the sensor 5c corresponds to an illuminance of 100%, the UV lamp 5c is moved up by the lamp movement driving unit 5b to make an adjustment so that the amount of UV light reaching the wafer W corresponds to a illuminance of 70%. When the amount of light detected by the sensor 5c is smaller than that corresponding to an illuminance of 100%, the lamp movement driving unit 5b is adjusted so that the gap between the wafer W and UV lamp 5a is reduced according to the difference between the detected amount of light and the illuminance of 100%. Such adjustment is performed each time of irradiation (every time) or regularly. This can prevent the amount of UV light projected on the wafer W from fluctuating. It is therefore possible to reliably and stably perform the surface modification for the rear surface (application surface) of the wafer W.

The attenuation of UV light of the UV lamp 5a is the largest at the first use of the UV lamp 5a and tends to gradually degrease as the UV lamp 5 comes close to the end of the UV lamp's life. Accordingly, the adjustment amount of the gap between the wafer W and the lamp 5a should be gradually reduced with time according to the attenuation of the UV light.

The various conditions for the adjustment include, in addition to the aforementioned distance between the wafer W and the UV lamp 5a, the intensity of the UV lamp 5a (input voltage of the UV lamp 5a), the irradiation time thereof (relative speed of the wafer W to the UV lamp 5a), the supply of reactive gas such as nitrogen or oxygen (flow rate of gas), and the like. For example, in the case of adjusting the input voltage of the UV lamp 5a, even when the lamp illuminance is higher than 70% before the end of the lamp's life, the input voltage is controlled so as to maintain the illuminance at 70%. Moreover, in the case of adjusting the irradiation time, the speed of the hand 3a moved by the arm 3b of the transport section 3 is reduced according to the decrease in lamp illuminance so that the integrated amount of light projected on the application surface of the wafer W per unit area is maintained constant. Moreover, the effect of UV light on surface modification of the application surface of the wafer W is influenced by the lamp illuminance and the concentration of the gas atmosphere around the application surface. Accordingly, the supply of gas is adjusted based on the supply of gas (the concentration of gas) which can provide a desired surface modification effect when the lamp illuminance is 70%. When the lamp illuminance is higher than 70%, the supply of gas (the concentration of gas) is reduced according to the difference between the lamp illuminance and 70% lump illuminance. The distance between the wafer W and the UV lamp 5a may be performed by the moving up and down function of the transport section 3 instead of the lamp movement driving unit 5b.

In addition, irradiation of UV light may be performed by a one-time irradiation method irradiating the entire surface of the wafer W from a fixed position, a scanning method, a rotating irradiation method, or the like. The irradiation section 5 may have a structure capable of irradiating the wafer W placed on a roller conveyer, a stage, a proximity pin, a robot arm, or the like.

As illustrated in FIG. 1, the application section 6 includes: a stage 6a on which the wafer W is placed; a stage transport driving unit 6b moving the stage 6a in the X-axis direction; a plurality of application heads 6c discharging the adhesive onto the wafer W on the stage 6a by an ink jet method for application; a liquid feeding unit 6d supplying the adhesive to each application head 6c; a discharge stabilization unit 6e stabilizing the discharge performance of each application head 6c; and a cleaning unit 6f cleaning the application surface of the wafer W on the stage 6a. In FIG. 1, a support unit supporting each of the application heads 6c is not illustrated.

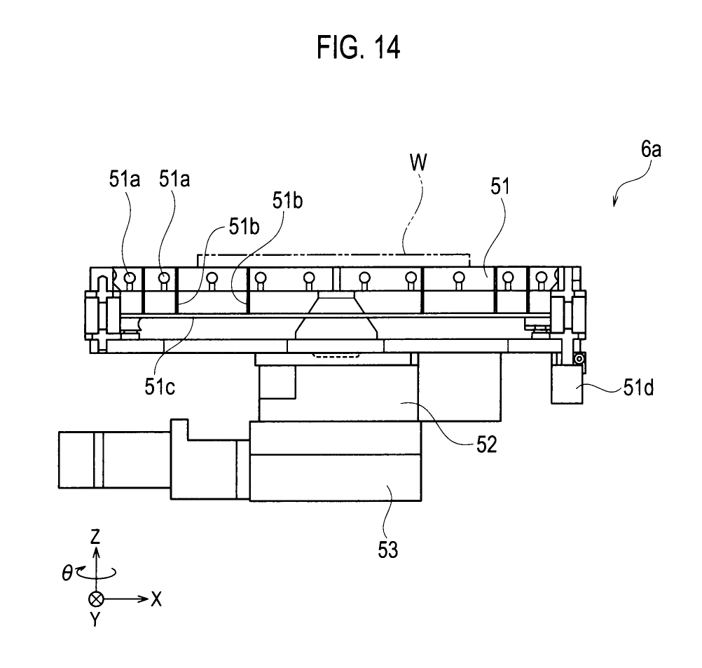

As illustrated in FIG. 14, the stage 6a includes: a heating stage 51 heating the wafer W placed thereon; a rotation driving portion 52 rotating the heating stage 51 in a plane; and a movement driving portion 53 moving the heating stage 51 in the Y-axis direction through the rotation driving portion 52. The stage 6a is provided on the rack 1a through the stage transport driving unit 6b.

The heating stage 51 is a placement table on which the wafer W is horizontally placed and heats the placed wafer W. The heating stage 51 incorporates stick-shaped heaters 51a which are arranged side by side in the Y-axis direction at substantially regular intervals. The intervals between the heaters 51a in each end (both sides) are smaller than those in the central part. Since there are no heaters outside of the heater 51a located at each end, the peripheral part of the heating stage 51 releases a larger amount of heat than the central part, and the temperature of the peripheral part is more likely to fall. Accordingly, the heater 51a located at each end is placed closer to the adjacent heater 51a to prevent reduction in temperature due to the heat release. The wafer W is heated by the heating stage 51 in order to accelerate drying of the adhesive applied to the application surface of the wafer W.

The temperature of the heating stage 51 is adjusted by feedback control using a temperature measurement equipment such as a temperature measuring resistor. There is a difference between the measurement value of the temperature measuring resistor inserted into the heating stage 51 as the temperature measurement equipment and the temperature of the surface of the heating stage 51, and this difference in temperature is previously compensated to set the temperature for control.

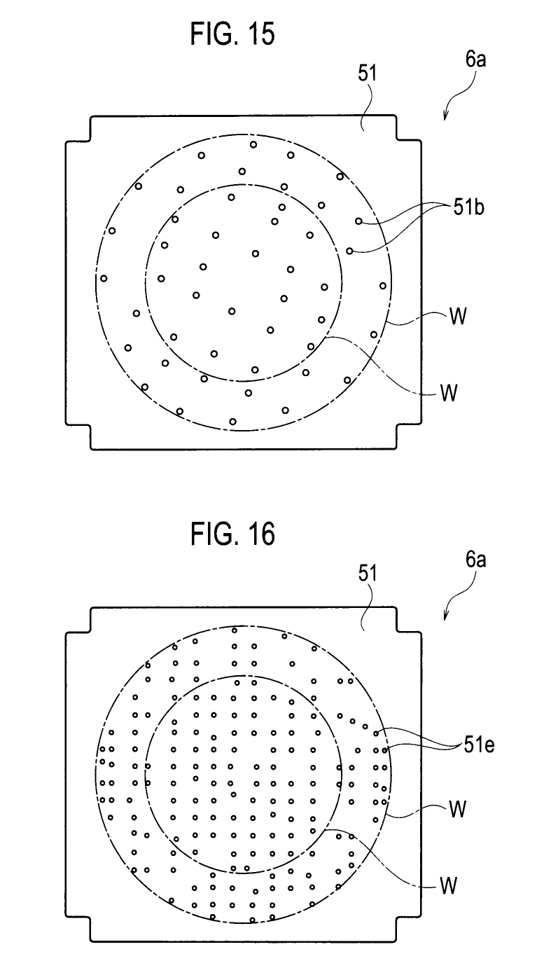

The hating stage 51 is provided with a plurality of stick-shaped lift pins 51b capable of moving up and down. The lift pins 51b are pins used to exchange the wafer W with the hand 3a of the transport section 3. The lift pins 51b are stood on the support plate 51c. The support plate 51c is placed under the heating stage 51 and is configured to move up and down through an air cylinder 51d. All of the lift pins 51b therefore simultaneously move up and down. As illustrated in FIG. 15, the lift pins 51b are arranged other than in the place where the heaters 51a are provided so as not to interfere with the hand 3a positioned on the stage 6a at exchanging the wafer W.

As illustrated in FIG. 16, the heating stage 51 is provided with a plurality of suction holes 51e. The suction holes 51e are evenly distributed in the region where the wafer W is held other than the places where the heaters 51a and lift pins 51b are arranged. The suction holes 51e communicate with a suction channel (not illustrated). The suction channel is connected to a suction unit (not illustrated) such as a suction pump through piping such as tubes or pipes. The suction channel for the suction holes 51e is configured to be changeable according to the size of the wafer W (8 or 12 inch, for example). Specifically, it is possible to switch between the suction channel allowing suction force to act on only the suction holes 51e located corresponding to small wafer W illustrated in FIG. 16 and the suction channel allowing suction force to act on the suction holes 51a located corresponding to both large wafer W and small wafer W illustrated in FIG. 16.

In order to reduce the unevenness of temperature in the heating stage 51, the lift pins 51b should have smaller diameter. In light of lifting weight of the wafer W, the pin diameter and hole diameter are set to 1.0 mm and 2.5 mm, respectively. This can prevent unevenness in temperature and lifting failure. Moreover, in order to reduce the unevenness in temperature of the heating stage 51, the hole diameter of the suction holes 51e should be smaller. For example, the hole diameter of 0.6 mm can prevent the unevenness in temperature and failure in suction. Moreover, in order to prevent crack caused by deformation of the wafer W due to the suction, the hole diameter of the suction holes 51e is desirably not more than 0.6 mm. It is thought that the effect of reducing the unevenness in temperature can be increased by reducing the diameter of the lift pins 51b to less than 1.0 mm. However, the rigidity of the lift pins 51b is degraded. Accordingly, in the case of reducing the diameter of the lift pins 51b to less than 1.0 mm, the diameter of the lift pins 51b should be reduced so as not to affect the up and down movement of the wafer W based on the relation between the weight of the wafer W and the number of lift pins 51b. The smaller the hole diameter of the suction holes 51e, the higher the effect of preventing the unevenness in temperature, but the lower the suction force. Accordingly, the hole diameter of the suction holes 51e should be reduced so as not to affect the suction of the wafer W based on the relation between the suction force of each suction hole 51e and the number of suction holes 51e.

The rotation driving unit 52 is a rotating mechanism supporting the heating stage 51 and rotating the same in the θ direction as illustrated in FIG. 14. The rotation driving unit 52 is electrically connected to the controller 8, and the driving of thereof is controlled by the controller 8.

The movement driving unit 53 is a moving mechanism supporting and moving the rotation driving unit 52 in the Y-axis direction. The movement driving unit 53 is electrically connected to the controller 8, and the driving of thereof is controlled by the controller 8. The movement driving unit 53 is composed of a feed screw-type driving unit using a servomotor as a driving source, a linear motor-type driving unit using a linear motor as a driving source, or the like, for example.

As illustrated in FIG. 1, the stage transport driving unit 6b includes: a frame 61 which supports the stage 6a and is elongated in the Y-axis direction; a movement driving portion 62 supporting one end of the frame 61 and moving the frame 61 in the X-axis direction; and a guide 63 supporting the other end of the frame 61 so as to move the same in the X-axis direction.

The stage transport driving unit 6b is a moving mechanism guiding and moving the stage 6a in the X-axis direction and is provided on the rack 1a. The movement driving portion 62 is electrically connected to the controller 8, and the driving thereof is controlled by the controller 8. The movement driving portion 62 is composed of a feed screw-type driving unit using a servomotor as a driving source, a linear motor-type driving unit using a linear motor as a driving source, or the like, for example.

Above a standby position where the stage 6a in the stage transport driving unit 6b is located when exchanging the wafer W with the hand 3a of the transport 3, an imaging portion 65 such as a camera is provided. The imaging portion 65 is supported by a Y-axis direction driving portion 66 so as to move in the Y axis direction with the image shooting direction set vertically downward. The Y-axis direction driving portion 66 is supported on the rack 1a by a not-illustrated support member. The imaging portion 65 takes an image of the periphery of the wafer W including corners C (see FIG. 11) of two chips located symmetrically with respect to a straight line passing through the notch and the center of the wafer W. At this time, the imaging portion 65 is moved by the Y-axis direction driving portion 66 from the position for shooting an image of the corner C of one of the chips to the position for shooting an image the corner C of the other chip.

The storage of the controller 8 previously stores information indicating the necessity of position detection such as information whether each wafer W accommodated in the accommodation sections 2 is pre-diced or not. It is then determined based on the stored information whether to execute the position detection using the imaging portion 65 for the wafer W placed on the stage 6a. When the position detection is necessary (when the wafer W is pre-diced, for example), the position detection is executed.

As for the case where the wafer W to be supplied is undiced; the adhesive film is formed in a circle to the region where the notch N is formed except the notch N; and the adhesive can be applied by the application section 6 properly at a positioning accuracy by the centering portion 4a and pre-alignment unit 4b, information that the pre-alignment is necessary and information that the position detection using the imaging portion 65 is unnecessary are stored in advance. In such a case, the control is made so that the pre-alignment is executed and the position detection is not executed.

Each of the application heads 6c is a discharge head discharging a plurality of droplets of adhesive liquid by an ink jet method toward the wafer W placed on the stage 6a. In this embodiment, the number of application heads 6c is seven, for example. The application heads 6c are arranged in a checkered pattern including two lines in the Y-axis direction. The application heads 6c are provided so as to discharge droplets of adhesive liquid onto the wafer W on the moving stage 6a. The application heads 6c are electrically connected to the controller 8, and the driving thereof are controlled by the controller 8.

Each of the application heads 6c includes a plurality of discharge holes (orifices) through which the droplets are discharged and incorporates a plurality of piezoelectric elements in the respective discharge holes. In each of the application heads 6c, the droplets are discharged from each of the discharge holes according to applied driving voltage of each of the piezoelectric elements controlled by the controller 8. The discharge holes are formed in a discharge surface (an orifice surface) of the application head 6c and linearly arranged in one or two lines at predetermined intervals. The nozzles of the seven application heads 6c are arranged over the entire length in the Y-axis direction. Moreover, the nozzles of the seven application heads 6c are arranged at regular intervals when seen in the X-axis direction.

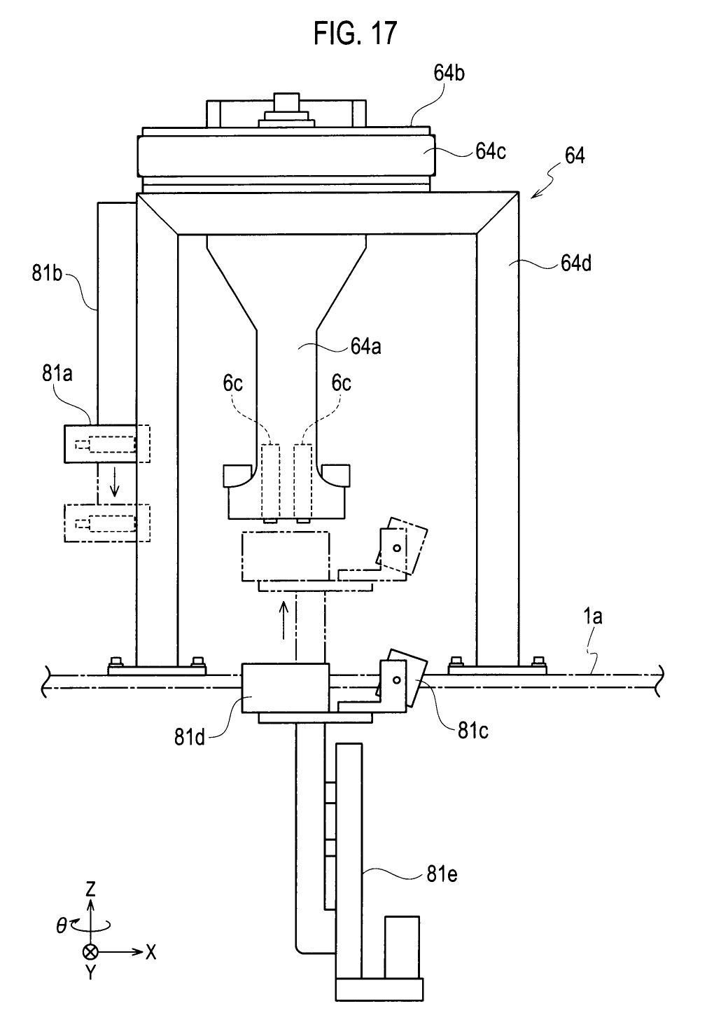

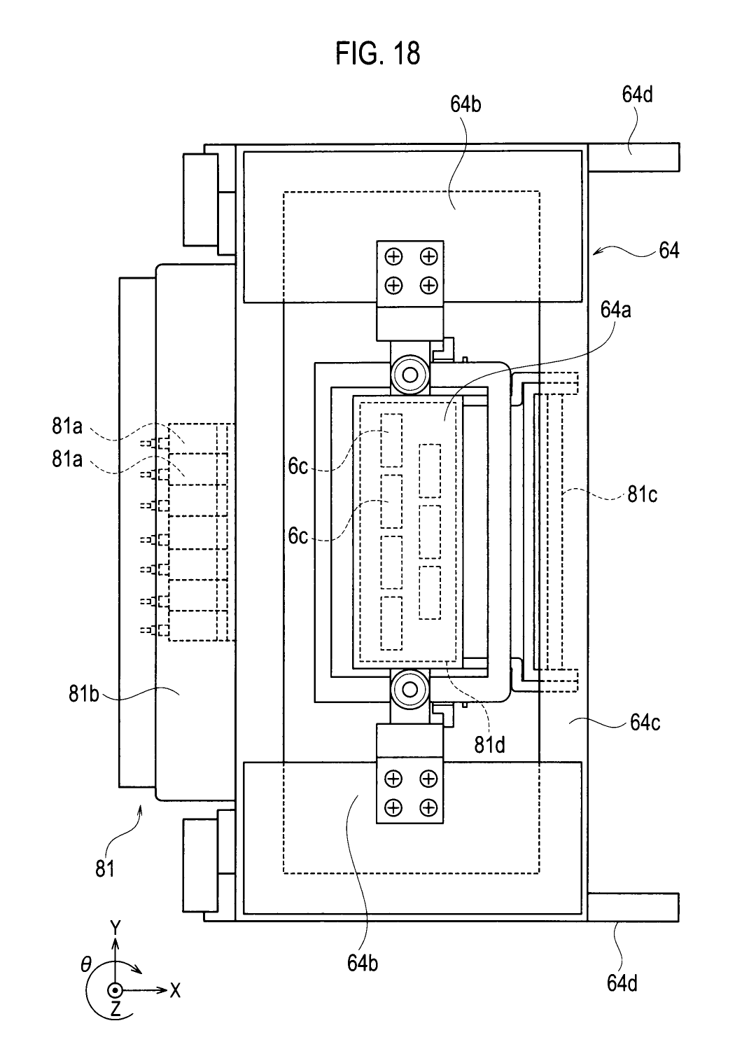

The application heads 6c are supported by a support portion 64 so as to discharge adhesive toward the wafer W on the moving stage 6a (see FIGS. 17 and 18). As illustrated in FIGS. 17 and 18, the support portion 64 includes: a holding member 64a incorporating and holding the application heads 6c; a pair of support plates 64b supporting the holding member 64a; a frame body 64c supporting the pair of support plates 64b with the holding member 64a set at the center; and a pair of gate members 64d supporting the frame body 64c.

The holding member 64a is elongated in the Y-axis direction and incorporates and holds the application heads 6c with the discharge surfaces of the application heads 6c exposed. The pair of support plates 64b support the holding member 64a on both sides in the Y-axis direction. The frame body 64c is elongated in the Y-direction and positioned over the moving stage 6a and the stage transport driving portion 6b. The frame body 64c is provided on the rack 1a by the pair of gates 64d. Each of the gate members 64d has a gate shape elongated in the X-axis direction. Crossbar part of the gate member 64d extends in parallel to the X-axis direction, and pillar parts of the gate member 64d are fixed to the upper surface of the rack 1a.

In the embodiment of the present invention, the pair of gates 64d are fixed to the rack 1a to limit the movement of the application heads 6c in the X-axis direction but not limited to this. The application heads 6c may be configured to move in the X-axis direction by allowing the pair of gates 64d to move in the X-axis direction.

As illustrated in FIG. 1, the liquid feeding unit 6d includes a pressurized tank 71 accommodating adhesive liquid; a supply tank 72 supplying the adhesive to each of the application heads 6c through piping such as tubes and pipes; and a waste tank 73 accommodating waste liquid. The liquid feeding unit 6d is electrically connected to the controller 8, and the driving thereof is controlled by the controller 8. The height of the liquid surface of the adhesive liquid reserved in the supply tank 72 is controlled so as to be equal to the discharge surface of the application heads 6c. When the liquid surface reaches such a height that replenishment is required, the adhesive liquid is supplied under pressure from the pressurized tank 71 enough to fill the gap.

As illustrated in FIG. 1, the discharge stabilization unit 6e includes: a discharge checking portion 81 checking discharge of each of the application heads 6c; a cleaning moisturizing portion 82 cleaning and moisturizing the discharge surface (orifice surface) of each of the application heads 6c; and a discharge amount checking portion 83 checking the total amount of adhesive liquid discharged from each of the application heads 6c.

As illustrated in FIGS. 1 and 18, the discharge checking portion 81 includes a plurality of imaging portions 81a (seven in the embodiment) provided corresponding to the individual application heads 6c; a first up and down movement driving portion 81b moving up and down the imaging portion 81a between a retracted position and an image shooting position; an illumination portion 81c for image shooting; a receiver portion 81d receiving droplets discharged from the application heads 6c; and a second up and down movement driving portion 81e moving up and down the illumination portion 81c and receiver portion 81d (see FIG. 17).

Each of the imaging portions 81a is provided for the individual application heads 6c. The imaging portions 81a are arranged in a line in the Y-axis direction. The imaging portions 81a are configured to move up and down between the retracted position out of the way of the application operation and an operation position as the image shooting position to check the discharge. The retracted position and image shooting position are located above the region where the stage 6a moves in the X-axis direction. The imaging portion 81a is electrically connected to the controller 8, and the driving thereof is controlled by the controller 8. The imaging portion 81a is composed of a CCD camera or the like, for example.

The up and down movement driving portion 81b is a moving mechanism provided for the frame body 64c of the support portion 64 and is configured to move up and down all the imaging portions 81a together. The up and down movement driving portion 81b is provided with an air cylinder which is driven to move up and down all the imaging portions 81a. The up and down movement driving portion 81b is electrically connected to the controller 8, and the driving thereof is controlled by the controller 8. The imaging portions 81a are positioned at the operation and retracted positions by the up and down movement driving portion 81b. The operation position of each imaging portion 81a is such the optical axis of the imaging portion 81a is located a little below the nozzle formation surface (lower surface) of the corresponding application head 6c so that images of the droplets which are discharged from the application heads 6c and are flying can be taken. The retracted position of each imaging portion 81a is located above the operation position and over the moving region of the stage 6a moving in the X-axis direction under the application heads 6c. The imaging portions 81a at the retracted position can be therefore prevented from interfering with the stage 6a.

The illumination portion 81c supplies enough light for all the imaging portions 81a to perform shooting operation. The illumination portion 81c is configured to move up and down between the retracted position out of the way of the application operation and the operation position as the irradiation position where the illumination portion 81c performs irradiation of light for checking discharge. The irradiation position of the illumination portion 81c is on the other side of the application heads 6c from the imaging portions 81a and is below all the application heads 6c. Moreover, the tilt of the illumination portion 81c is adjustable. The illumination portion 81c is tilted so as to irradiate the discharge surface of the application heads 6c with light at the irradiation position. The illumination portion 81c is electrically connected to the controller 8, and the driving thereof is controlled by the controller 8. The illumination portion 81c is composed of a linear illumination or the like, for example. An example of the linear illumination is an illumination composed of LEDs or the like arranged in a line.

The receiver portion 81d is a member receiving and accommodating the droplets discharged from the application heads 6c during the discharge check. The receiver portion 81d is provided so as to face the application heads 6c supported by the support portion 64. The receiver portion 81d is configured to move up and down between the retracted position out of the way of the application operation and the operation position as a receiving position at which the receiver portion 81d receives the droplets during the discharge check. The receiver portion 81d is connected to the waste tank 73 of the liquid feeding unit 6d through piping such as tubes and pipes and is configured to discharge the droplets received from the application heads 6c to the waste tank 73 through the piping as waste liquid.

The up and down movement driving portion 81e is a moving mechanism provided within the rack 1a under the support portion 64 and configured to support and move the illumination portion 81c and receiver portion 81d. The up and down movement driving portion 81e is electrically connected to the controller 8, and the driving thereof is controlled by the controller 8. The up and down movement driving portion 81e is composed of a feed screw-type driving unit using a servomotor as a driving source or the like, for example. The illumination portion 81c and the receiver portion 81d are positioned at the operation positions and retracted positions by the up and down movement driving portion 81e. The operation position of the illumination portion 81c is at such a height that the direction that the illumination portion 81c projects light is directed to the positions where the optical axes of the imaging portions 81a positioned at the operation position intersects the direction that the droplets discharged from the nozzles of the application heads 6c fly. The operation position of the receiver portion 81d is at such a height that gap allowing the imaging portions 81a to shoot images of the droplets is formed between the upper edge of the receiver portion 81d and the nozzle formation surfaces of the application heads 6c. The retracted positions of the illumination portion 81c and receiver portion 81d are below the respective operation positions and under the moving region of the stage 6a moving in the X-axis direction under the application heads 6c. The illumination portions 81c and the receiver portion 81d at the retracted positions are prevented from interfering with the stage 6a. In other words, the stage 6a passes over the illumination portion 81c and receiver portion 81d positioned at the retracted positions.

The discharge check portion 81 moves the imaging portions 81a, the illumination portion 81c, and the receiver portion 81d to the respective operation positions and turns on the illumination portion 81c to generate enough light to shoot images. The discharge check portion 81 then takes images of the droplets discharged from the application heads 6c with the respective imaging portions 81a and performs image processing for the images to compare the obtained images with a normal image in terms of the straightness and shape of the droplets or the like, thus checking the conditions of the application heads 6c. After the check, the discharge check portion 81 turns off the illumination portion 81c and moves the receiver portion 81d to the retracted position.

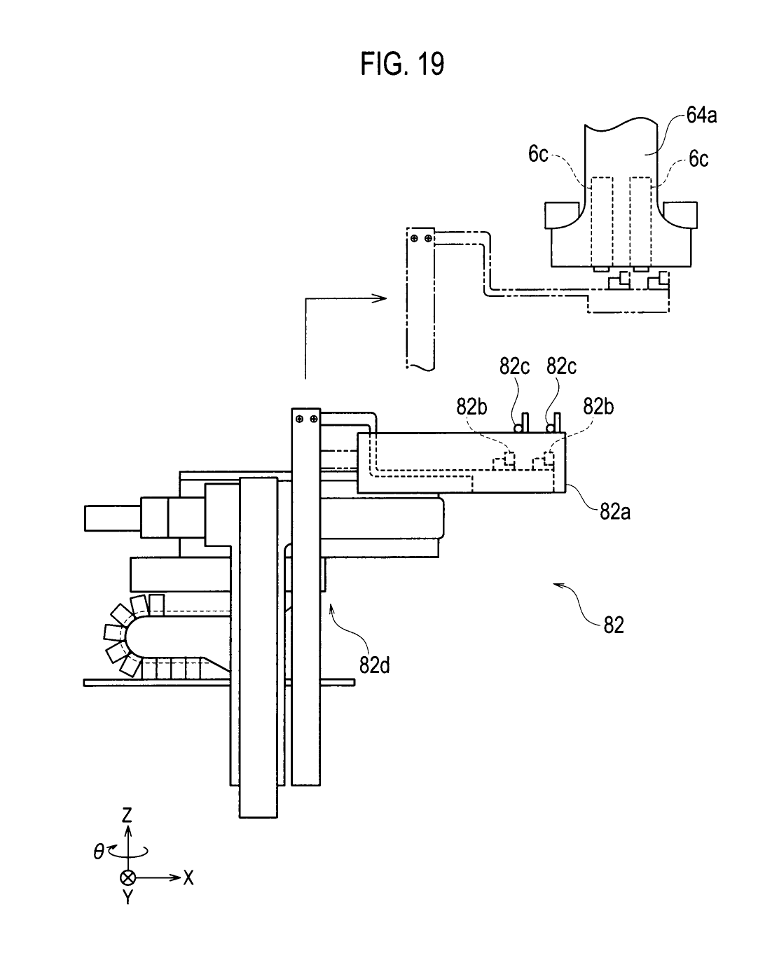

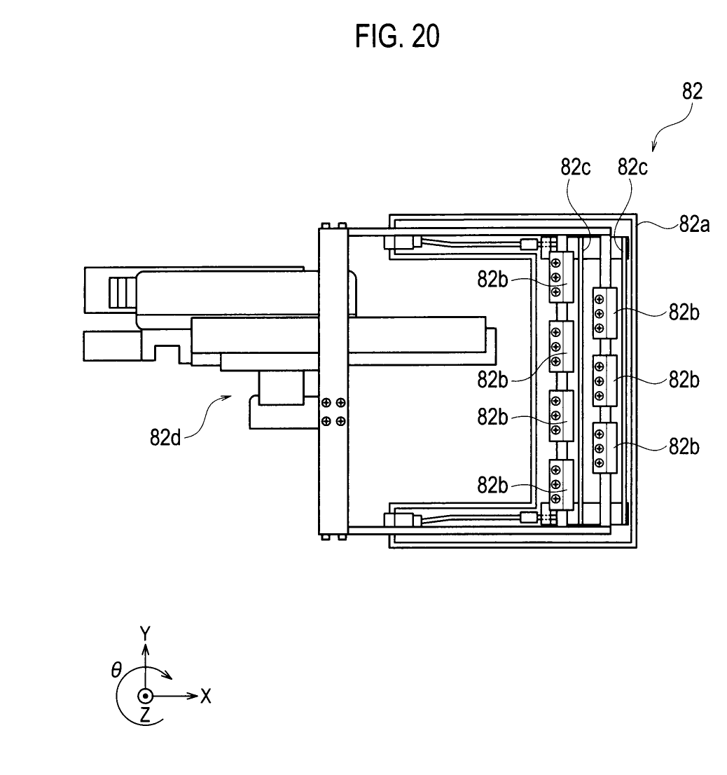

As illustrated in FIGS. 19 and 20, the cleaning moisturizing portion 82 includes: a box-shaped vessel 82a open at the top; a plurality of wiping members 82b provided within the vessel 82a; nozzles 82c spraying a solvent of the adhesive to the wiping members 82b; and a movement driving portion (a first movement driving portion) 82d moving the vessel 82a up and down and in the X-axis direction. The solvent is preferably a solvent contained in the adhesive.

The vessel 82a moves between a retracted position and an operation position so as to prevent the vessel 82 from being in the way of the stage 6a moving in the X-axis direction. The retracted position is located below the height where the stage 6a moves. The operation position is a wiping position where the vessel 82a can come into contact with the discharge surfaces (nozzle formation surfaces) of the application heads 6c. The vessel 82a moves in the X-axis direction so that each wiping member 82b moves at least from one end of the discharge surface of the corresponding application head 6c to the other end in the X-axis direction. The wiping members 82b provided within the vessel 82a move together with the vessel 82a. The vessel 82a at the retracted position is adjacent to the receiver portion 81d of the discharge check portion 81 located at the retracted position on the transport section 3 side in the X-axis direction.

The wiping members 82b are individually provided for the respective application heads 6c and are arranged in two lines in the Y-axis direction. The wiping members 82b are wetted and wipe the discharge surfaces of the application heads 6c to clean and moisturize the discharge surfaces of the application heads 6c. The wiping members 82b are made of water-absorbing material, for example. The wiping members 82b may be composed of blades of an elastic material such as rubber when the adhesive sticking to the discharge surfaces can be scraped and cleaned.

The nozzles 82c are nozzles spraying the solvent to the wiping members 82b to make the wiping members 82b wet before the wiping members 82b wipe the discharge surfaces of the application heads 6c. Each of the nozzles 82c is tube-shaped and extended in the Y-axis direction. The nozzle 82c is provided with a plurality of through holes (not illustrated) corresponding to the wiping members 82c for spraying the solvent.

The movement driving portion 82d is a moving mechanism provided under the support portion 64 in the rack 1a, and is configured to support and move the vessel 82a and wiping members 82b up and down and in the X-axis direction. The moving driving portion 82d is composed of a combination of the up and down movement driving unit and X-axis direction driving unit. The movement driving portion 82d is electrically connected to the controller 8, and the driving thereof is controlled by the controller 8. The up and down movement driving unit and X-axis direction driving unit constituting the movement driving portion 82d are composed of a feed screw-type driving unit using a servomotor as a driving source, a liner motor-type driving unit using a linear motor as a driving source, or the like, for example.

The cleaning moisturizing portion 82 moves the vessel 82a with the movement driving portion 82d from the retracted position to the initial standby position through the wiping position to wipe the discharge surfaces of the application heads 6c with the corresponding wiping members 82b within the vessel 82a and moisturize the discharge surfaces of the application heads 6c. The wipe members 82b get wet due to the supply of the solvent by the nozzles 82c.

In the aforementioned case, the wiping members 82b are water-absorbing. Accordingly, when the discharge surfaces of the application heads 6c are wiped, the wiped adhesive is absorbed by the wiping members 82b and will not drop from the wiping members 82b. The vessel 82a and nozzles 82c may be therefore fixed to the standby positions while only the wiping members 82b are moved from the retracted positions to the wiping positions by the movement driving portion 82d.

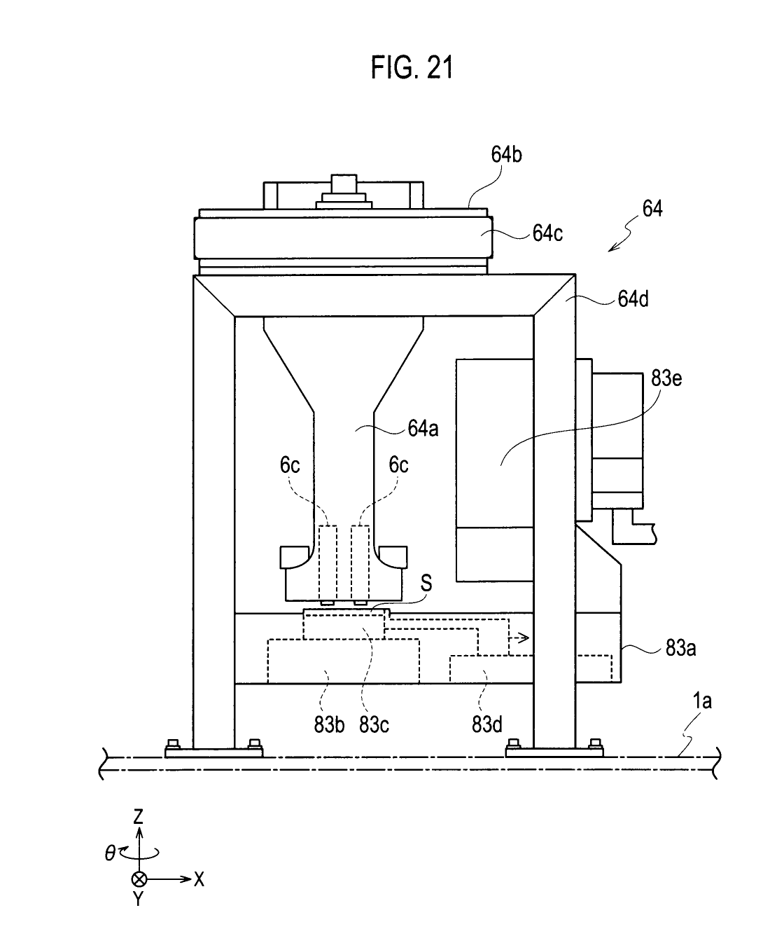

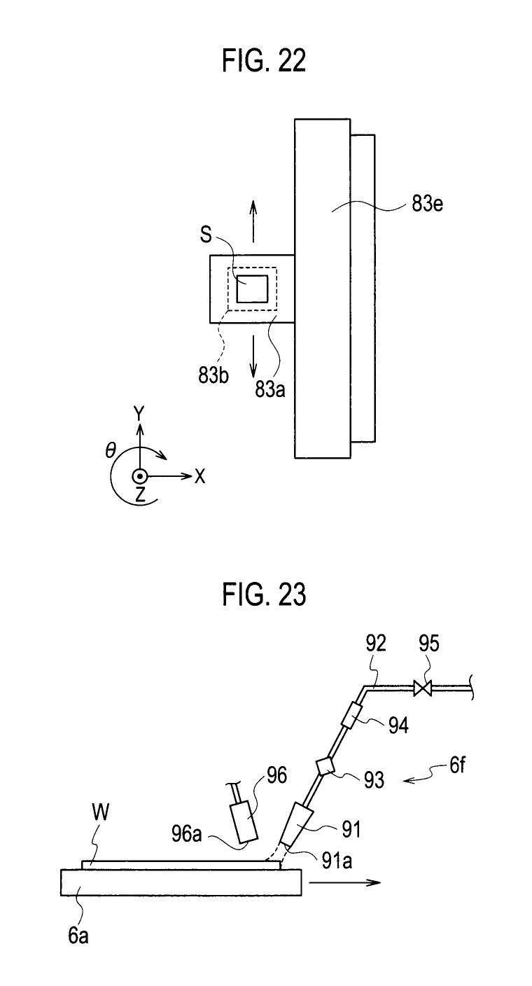

As illustrated in FIGS. 21 and 22, the discharge amount checking portion 83 includes: a box-shaped casing 83a provided with a shutter S; an electronic balance 83b for measurement; a measuring vessel 83c provided on the electronic balance 83b; a shutter driving portion 83d opening and closing the shutter S; and a movement driving portion (a second movement driving portion) 83e moving the casing 83a in the Y-axis direction.

The casing 83a is configured to move to the retracted position out of the way of the application operation and the operation position determined for each application head 6c as a measuring position. When the casing 83a is located at the operation positions, the measuring vessel 83c is positioned under the corresponding application head 6c. The casing 83a is held by the movement driving portion 83e. The retracted position of the casing 83a is set on the side of the moving region of the stage 6a moving in the X-axis direction. In the casing 83a, the openable and closable shutter S is formed. The shutter 83 is opened and closed when the measurement is performed.

The electronic balance 83b is provided under the shutter S within the casing 83a and measures the weight of the substance within the measuring vessels 83c. The electronic balance 83b is electrically connected to the controller 8, and the driving thereof is controlled by the controller 8. The electronic balance 83b outputs the measurement results to the controller 8.

The measuring vessel 83c is provided on the electronic balance 83b within the casing 83a and accumulates the droplets discharged from each application head 6c. The measuring vessel 83c is quadrangular in a plan view. A dimension of the measuring vessel 83c in the Y-axis direction is long enough to catch all the droplets discharged one of the application heads 6c. A dimension of the measuring vessel 83c in the X-axis direction is long enough to catch droplets discharged from both of the two application heads 6c arranged side by side without changing the position thereof in the X-axis direction.

The shutter driving portion 83d is a moving mechanism provided in the casing 83a and configured to move the shutter S in the X-axis direction. The shutter driving portion 83d is provided with an air cylinder and drives the air cylinder to move the shutter S in the X-axis direction for opening and closing the casing 83a. The shutter S is electrically connected to the controller 8, and the driving thereof is controlled by the controller 8.

The movement driving portion 83e is provided above the moving region of the stage 6a in the X-axis direction and supports the casing 83a hanging. The movement driving portion 83e is electrically connected to the controller 8, and the driving thereof is controlled by the controller 8. The movement driving portion 83e is composed of a feed screw-type driving portion using a servomotor as a driving source, a linear motor-type driving portion using a linear motor as a driving source, or the like, for example.

The discharge amount checking portion 83 moves the electronic balance 83b to the measurement position in the Y-axis direction to position the casing 83a or the measurement vessel 83c under the application heads 6c and then opens the shutter S. After droplets are discharged from all the nozzles of the application heads 6c for a setting number of times, the discharge amount checking portion 83 closes the shutter S. Based on the difference between the outputs of the electronic balance 83b before and after the discharge, the total amount of all the droplets discharged from each application head 6c is sequentially calculated. After the measurement, the discharge amount checking portion 83 moves the electronic balance 83b or the casing 83a to the standby position in the Y-axis direction.

As illustrated in FIG. 23, the cleaning portion 6f includes: a nozzle 91 blowing gas such as nitrogen or air; piping 92 feeding the gas to the nozzle 91; a filter 93; a flow rate regulation valve 94; a opening/closing valve 95; and a suction portion 96 sucking air together with foreign substances such as dust and dirt which are scattered from the wafer W on the stage 6a by the gas blown by the nozzle 91. The filter 93, The flow rate regulation valve 94, and the opening/closing valve 95 are provided in the middle of the path of the piping 92.

The nozzle 91 includes a blow outlet 91a as an opening through which gas is blown onto the wafer W on the moving stage 6a. The nozzle 91 is provided above the moving region of the stage 6a in the X-axis direction with the blow outlet 91a facing the moving region in the X-axis direction. The nozzle 91 is composed of a nozzle having a slit-shaped blow outlet, the slit extending in the Y-axis direction, or a nozzle having a plurality of circular blow outlets arranged in the Y-axis direction, for example. The blow outlet 91a in the Y-axis direction has a dimension equal to or longer than the length of the stage 6a in the Y-axis direction.

The piping 92 is composed of tubes and pipes communicating the nozzle 91 and a gas supply portion (not illustrated). The filter 93 is a member removing foreign substances from gas passing through the piping 92. The flow rate regulation valve 94 is a valve regulating the flow rate of gas flowing through the piping 92. The opening/closing valve 94 is a valve opening and closing the piping 92. The flow rate regulation valve 94 and opening/closing valve 95 are electrically connected to the controller 8, and the driving thereof are controlled by the controller 8.

The suction portion 96 has a box shape provided with an opening extending in the Y-axis direction as a suction port 96a. The suction portion 96 is provided above the X-axis direction moving region of the stage 6a with the suction portion 96a facing the X-axis direction moving region. The suction port 96a has a dimension in the Y-axis direction equal to or longer than the length of the stage 6a in the Y-axis direction. Preferably, an opening area of the suction port 96 is larger than the opening area of the blow outlet 91a of the nozzle 91 and the suction port 96 in the Y-axis direction is equal to or longer than the length of the blow outlet 91a in the Y-axis direction. Moreover, it is preferable that the flow rate of gas sucked through the suction port 96a of the suction portion 96 is higher than that of gas blown out through the blow outlet 96a of the nozzle 91.

The cleaning portion 6f blows gas onto the wafer W on the moving stage 6a through the nozzle 91 to clean the application surface of the wafer W. The application surface of the wafer W is therefore cleaned before the adhesive is applied thereto. This can prevent that foreign substances are on the application surface of the wafer W, thus improving the application quality of the wafer W. Moreover, the cleaning portion 6f sucks the foreign substances scattered from the application surface of the wafer W together with air by the suction portion 96. This can prevent the foreign substances scattered from the application surface of the wafer W from sticking to other part of the apparatus or sticking to the wafer W again. It is therefore possible to prevent contamination of the apparatus and recontamination of the wafer W.

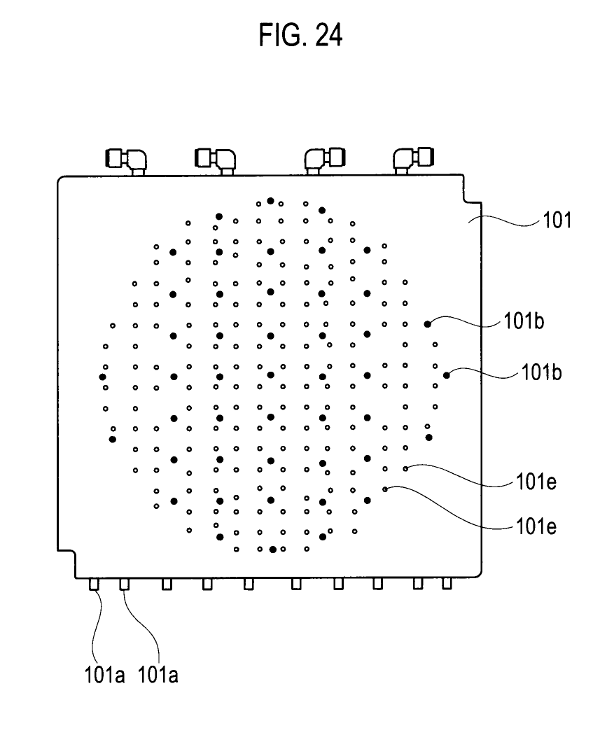

The drying section 7 performs initial drying for the adhesive applied to the wafer W before a curing process to cure the adhesive, which is performed as a post processing step separately from the processes of the semiconductor manufacturing apparatus 1. As illustrated in FIGS. 7 and 24, the drying section 7 includes a plurality of heater plates 101 and a support unit 102 supporting the heater plates 101 layered in at predetermined intervals. In the embodiment, the number of layers of the heater plates 101 is five, for example.

Each of the heater plates 101 is a placement table on which the wafer W is placed horizontally and is configured to heat the placed wafer W. Each of the heater plates 101 incorporates stick-shaped heaters 101a arranged side by side at substantially regular intervals. The intervals of the heaters 101a located in the edge portions (at both ends) are narrower than those in the center. Since there are no heaters outside of the heaters 101a located at the both ends, the peripheral part of the heater plate 101 releases a larger amount of heat than the center part thereof. The temperature of the peripheral part is more likely to fall. Accordingly, the heater 101a located at each end is placed closer to the adjacent heater 101a to prevent reduction in temperature due to heat release. The wafer W is heated by the heater plate 101 in order to accelerate drying of the adhesive applied to the application surface of the wafer W.

The temperature of the heater plates 101 is adjusted by feedback control using a temperature measurement equipment T such as a temperature measuring resistor. The measurement value of the temperature measuring resistor inserted into a heater plate 101 as the temperature measurement equipment T is different from the temperature in the surface of the heater plate 101 (or ambient temperature). Accordingly, the difference therebetween is previously corrected to set a temperature for control. The temperature is set for a storage provided for the controller 8, for example.

Each of the heater plates 101 includes a plurality of stick-shaped lift pins 101b capable of moving up and down. The lift pins 101b are pins to exchange the wafer W with the hand 3a of the transport section 3. The lift pins 101b are stood on each of support plates 101c. Each of the support plates 101c is provided under the corresponding heater plate 101 and is configured to be moved up and down by air cylinders 101d. All the lift pins 101b on each support plate 101c can therefore move up and down simultaneously. As illustrated in FIG. 24, the lift pins 101b are arranged other than the places where the heaters 101a are provided so as not to interfere with the hand 3a inserted over the heater plate for exchange of the wafer W.

The plurality of lift pins 101b, support plate 101c, and air cylinders 101d for each heater plate 101 function as one switching unit. The switching unit switches between a contact state in which the wafer W is in contact with the heater plate 101 and a separating state in which the wafer W is a predetermined distance away from the heater plate 101. The wafer W is dried by heat of the heater plate 101 at any one of the contact and separate states.

As illustrated in FIG. 24, each of the heater plates 101 includes a plurality of suction holes 101e. The suction holes 101e are substantially evenly distributed in the region where the wafer W is held other than the places where the heater 101a and the lift pins 101b are arranged. The suction holes 101e communicate with a suction channel (not illustrated). The suction channel is connected to a suction unit (not illustrated) such as a suction pump through piping such as tubes and pipes.

The suction channel for the suction holes 101e is configured to be changeable according to the size of the wafer W (8 and 12 inches, for example). Specifically, it is possible to switch between the suction channel allowing suction force to act on only the suction holes 101e located corresponding to the suction range of the wafer W of small size and the suction channel allowing suction force to act on the suction holes 101a located corresponding to the suction ranges of both large and small wafers W.

In order to reduce the unevenness in temperature in each heater plate 101, the lift pins 101b should have a smaller diameter. In light of lifting weight of the wafer W, the pin diameter and hole diameter are set to 1.0 mm and 2.5 mm, respectively, for example. This can prevent the unevenness in temperature and failure in lifting. Moreover, in order to reduce the unevenness in temperature of each heater plate 101, the hole diameter of the suction holes 101e should be smaller. For example, the hole diameter set to 0.6 mm can prevent the unevenness in temperature and failure in suction. Moreover, in order to prevent crack caused by deformation of the wafer W due to the suction, the hole diameter of the suction holes 101e is desirably not more than 0.6 mm. It is thought that the effect of reducing the unevenness in temperature can be increased by reducing the diameter of the lift pins 101b to less than 1.0 mm. However, the rigidity of the lift pins 101b is degraded. Accordingly, in the case of reducing the diameter of the lift pins 101b to less than 1.0 mm, the diameter of the lift pins 101b should be reduced so as not to affect the up and down movement of the wafer W based on the relation between the weight of the wafer W and the number of lift pins 101b. The smaller the hole diameter of the suction holes 101e, the higher the effect of preventing the unevenness in temperature, but the lower the suction force. Accordingly, the hole diameter of the suction holes 101e should be reduced so as not to affect the suction of the wafer W based on the relation between the suction force of each suction hole 101e and the number of suction holes 101e.

In order to reduce drying unevenness due to the heater plates 101, the stop positions of the lift pins 101b may be changed by the controller 8 according to the temperature measured by the temperature measuring equipment T. The heater plates 101 are layered, and the temperature of space between the heater plates 101 is more likely to rise. Accordingly, it is difficult to reliably reduce the drying unevenness by controlling the temperature of the heater plates 101. The amount of heat given from each of the heater plates 101 to the wafer W can be controlled by changing the stop positions of the lift pins 101b to adjust the distance between the heater plate 101 and the wafer W. For example, when the temperature of the heater plate 101 increases more than necessity, the distance between the heater plate 101 and the wafer W is increased according to the increase in temperature. This allows the amount of heat given to the wafer W to be adjusted quicker than the case of controlling the temperature of the heater plate 101. It is therefore possible to prevent drying unevenness of the adhesive and uniformly dry the adhesive on the wafer W. Moreover, it is possible to adjust the stop positions of the lift pins 101b of each heater plate 101 so that the distance between each of the heater plates 101 and the corresponding wafer W increases from the bottom toward the top.

The distance between each of the heater plates 101 and the corresponding wafer W, or the stop positions of the lift pins 101b may be adjusted based on the result from the total judgment for the both temperatures measured by the temperature measuring equipment T and temperature measuring equipment measuring temperature of space above the heater plate 101. In such a case, it is possible to consider not only the amount of heat given by the heater plate 101 but also the amount of heat given by the atmosphere temperature, thus reducing the drying unevenness of the adhesive more reliably. The stop positions of the lift pins 101b may be adjusted based on only the result of measurement of the temperature of space above the heater plate 101.

The temperatures of the plurality of layered heater plates 101 may be set so that the temperature of the heater plate 101 located on the upper side is lower than that of the heater plate 101 located on the lower side. For example, the setting temperature is gradually decreased toward the heater plate 101 at the top, or the setting temperature of the heater plate 101 located at the top is set lower than temperatures of the other heater plates 101. This is because the upper heater plates 101 tends to become hotter since the air heated by each heater plate 101 rises along the wall plates 102a.

As illustrated in FIG. 7, the support portion 102 includes a pair of wall plates 102a and a plurality of support members 102b. The pair of wall plates 102a are arranged so as to sandwich the horizontally extended heater plates 101 in the horizontal direction. Each of the support members 102b is fixed to the pair of wall plates 102a so as to support the four corners of the heater plate 101. In other words, one heater plate 101 is supported by the four support members 102b. The support members 102b support each of the heater plates 101 with heat insulator members 102c interposed therebetween.

An operating rod of each of the air cylinders 101d is coupled with around the center of a coupling rod (not illustrated) horizontally provided. The both ends of the coupling rod are supported outside of the wall plate 102a with a guide member (not illustrated) interposed therebetween so as to move vertically. The coupling rod is also connected to the support plates 101c for the lift pins 101b. The lift pins 101b can be therefore moved vertically up and down by the air cylinder 101d.

As illustrated in FIG. 1, the controller 8 includes a microcomputer centralizedly controlling each section and a storage storing application information concerning the application, various types of programs, or the like. The controller 8 is connected to an operating unit 8a receiving an operation from the operator.

The application information includes a predetermined application pattern such as a dot pattern, information concerning frequency at which the application heads 6c discharge the adhesive and moving speed of the wafer W, and the like. The application information is previously stored in a storage through an entry operation at the operation unit 8a, data communication, or a portable memory device. The storage is composed of various types of memories, hard disk drives (HDD), and the like.

At the application operation, the controller 8 controls the application heads 6c and the stage transport driving unit 6b based on the application information, and at the discharge stabilization operation, the controller 8 controls the discharge stabilization unit 6e. Herein, the application operation refers to an operation of applying the adhesive to the wafer W on the stage 6a. The discharge stabilization operation includes the discharge checking operation, the wet wiping operation, the discharge amount checking operation, and the like.

Next, a description is given of an operation of manufacturing semiconductor devices (a manufacturing method) performed by the semiconductor device manufacturing apparatus 1. The controller 8 of the manufacturing apparatus 1 executes the manufacturing process (including a discharge stabilization process) based on various programs.

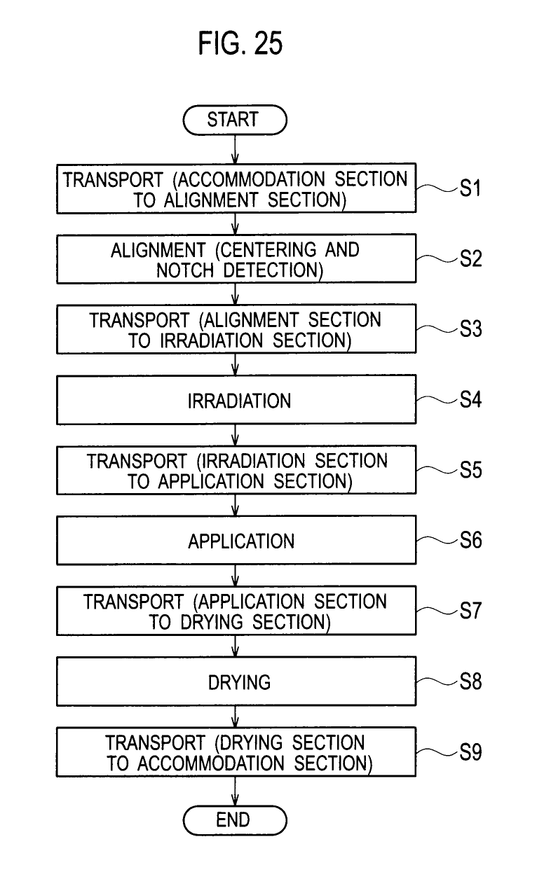

As illustrated in FIG. 25 (also see FIG. 1), a wafer W is taken out from one of the accommodation sections 2 by the transport section 3 and then transported to the alignment section 4 (step S1). First, the transport section 3 operates the arm 3b to take the wafer W out of the accommodation section 2 for supply by the hand 3a. To be more specific, the hand 3a is raised to the height position corresponding to the support plate 2a supporting the wafer W to be currently transported in the accommodation section 2 for supply, specifically to the position between the support plate 2a and the reinforcement member 12 of the support plate 2a. Next, the arm 3b is extended to insert the hand 3a under the wafer W supported by the support plate 2a. The arm 3b then moves up to cause the hand 3b to scoop the wafer W from underneath to suck and receive the same. After the arm 3b is contracted, the arm 3b is moved down to the original height position.

The arm 3b is then moved in the X-axis direction and rotated in the θ direction together with the hand 3a to stand by at the position for transfer to the alignment section 4. Subsequently, the transport section 3 operates the arm 3b to transfer the wafer W to the centering unit 4a of the alignment section 4 by the hand 3a. To be more specific, the transport section 3 extends the arm 3b in the direction indicated by the arrow A1 in FIG. 1 to move the hand 3a to over the support table 31 of the centering unit 4a and releases the wafer W sucked by the hand 3a. The transport section 3 then moves the arm 3b down to enter the hand 3a into the recess of the support table 31 to interdigtate the support portions 3a1 constituting the comb teeth of the hand 3a with the support portions 31a constituting the comb teeth of the support table 31. During the down movement, the wafer W on the hand 3a is placed on the support table 31.

Thereafter, the alignment is performed by the alignment section 4 (step S2). First, the centering unit 4a performs alignment of the wafer W to the hand 3a of the transport section 3. The centering unit 4a moves the levers 32a of the pressing portions 32 to the previously set stop positions in the three directions toward the wafer W on the support table 31 with the support portions 3a1 constituting the comb teeth of the hand 3a interdigitated with the support portions 31a constituting the comb teeth of the support table 31. The pins of the levers 32a are pressed against the outer edge of the wafer W to move the wafer W in one plane and align the center of the wafer W with the center of the support table 31. The centering unit 4a thus performs the alignment (centering) to align the center of the wafer W with the center of the hand 3a positioned with respect to the support table 31. After completion of the centering, the levers 32a retract to the original positions for standby.

Next, the pre-alignment unit 4b performs alignment in the θ direction. When the storage stores information requiring pre-alignment, the controller 8 causes the pre-alignment unit 4b to execute pre-alignment. First, the hand 3a intedigitated with the comb teeth of the support table 31 moves up; sucks and receives the wafer W placed on the support table 31; and then moves up to such a position that the holding portion 41 of the pre-alignment unit 4b can suck the wafer W. The pre-alignment unit 4b sucks the wafer W on the hand 3a to the bottom surface of the holding portion 41 and holds the same. The suction of the wafer W by the hand 3a is stopped when the wafer W can be properly transferred. After the transfer is completed, the hand 3a moves down a predetermined distance enough to not interfere with the rotation of the wafer W for standby. At this time, the pre-alignment unit 4b previously moves the imaging portion 43 to the shooting position according to the size of the current wafer W by the movement driving portion 44. Thereafter, the imaging portion 43 sequentially takes images of the peripheral part of the wafer W at set times through the openings H of the plates 45 and 46 while the holding portion 41 is being rotated by the rotation driving portion 42.

The pre-alignment unit 4b performs image processing for the taken images by the image processing computing unit at each shooting of the images and determines whether there is a pattern matching the image of the referential notch previously stored. If there is a pattern matching the image of the referential notch (the notch N), the pre-alignment unit 4b calculates the amount of correction based on the position of the notch N in the θ direction. The controller 8 then rotates the holding portion 41 by the calculated amount of correction and moves the hand 3a up until the hand 3a comes into contact with the lower surface of the wafer W held by the holding portion 41. When the hand 3a moves up and comes into contact with the lower surface of the wafer W, the controller 8 begins the attraction of the wafer W by the hand 3a and stops the suction of the wafer W by the holding portion 41 of the pre-alignment unit 4b to transfer the wafer W on the lower surface of the holding unit 41 to the hand 3a. The hand 3a receives the wafer W from the bottom surface of the holding portion 41 and sucks and holds the same, thus completing the alignment of the wafer W with respect to the hand 3a by the alignment section 4.

The wafer W is then transported from the alignment section 4 to the irradiation section 5 by the transport section 3 (step S3). When the hand 3a receives the wafer W from the holding unit 41 of the alignment section 4 and holds the same, the arm 3b is contracted to retract the hand 3a from the alignment section 4 and is then rotated in the θ direction, thus positioning the wafer W at the starting position of the irradiation operation of the irradiation section 5.

Next, irradiation of UV light is performed by the irradiation section 5 (step S4). The irradiation section 5 irradiates the application surface of the wafer W on the hand 3a being moved by the arm 3b with UV light by the UV lamp 5a for surface modification. At this time, the arm 3b is advanced and retracted to reciprocate the hand 3a under the UV lamp 5a. The illuminance of the UV lamp 5a is controlled to be constant at a predetermined value. After the irradiation, the hand 3a retracts to the same position as the starting position of the irradiation operation.

Next, the wafer W is transported from the irradiation section 5 to the application section 6 by the transport section 3 (step S5). The transport section 3 rotates the arm 3b in the θ direction to set the hand 3a to the position to transfer the wafer W to the application section 6 and then extends the arm 3b in the direction indicated by the arrow A2 in FIG. 1 to move the wafer W to the stage 6a positioned at the standby position in the application section 6 by the hand 3a. When the hand 3a is positioned at the stage 6a, the transport section 3 moves down the arm 3b. The stage 6a is on standby with the lift pins 51b raised, and the wafer W on the hand 3a moved down by the down movement of the arm 3b is transferred from the hand 3a to the lift pins 51b. The suction of the wafer W by the hand 3a is released until the wafer W comes into contact with the lift pins 51b after the down movement of the arm 3b starts.

At the transfer of the wafer W, the hand 3a is positioned with the center matching the center of the stage 6 waiting at the standby position (the center of rotation by the rotation driving portion 52). Although the center of the circle of the hold pins 21 is set to the center of the hand 3a, therefore, the center of the hand 3a may be set to the point on the hand 3a which is opposed to the center of the stage 6a when the hand 3a is positioned with respect to the stage 6a located at the standby position in the case where the hold pins 21 are not provided or in another case.

After the hand 3a is retracted from above the stage 6a by the contraction action of the arm 3b, the lift pins 51b are moved down to place the wafer W on the stage 6a, and the suction force of the suction holes 51e of the stage 6a is activated to suck and hold the wafer W. On the other hand, the hand 3a is waiting at the transfer position. Herein, the position where the transport section 3 exchanges the wafer W with the alignment section 4, the starting position of the irradiation operation by the irradiation section 5, and the position where the transport section 3 exchanges the wafer W with the application section 6 are located at the same position in the X-direction excepting that the hand 3 is directed in different directions.

Next, the application is performed by the application section 6 (step S6). When the wafer W placed on the stage 6a at the standby position by the hand 3a is undiced, the application section 6 moves the stage 6a from the standby position in the X-axis direction by the movement driving portion 53. On the other hand, when the wafer placed on the stage 6a is pre-diced, the application section 6 uses the imaging portion 65 to take an image including each of the corners C of two chips set on the wafer W. Based on the positional information of the two corners C obtained based on the taken images, the application section 6 detects misalignment of the wafer W in the X-axis, Y-axis, and θ directions at high accuracy. The application section 6 corrects the position of the stage 6a based on the detected misalignment and then moves the stage 6a from the standby position in the X-axis direction. As described above, the controller 8 causes the application section 6 to selectively execute the position detection based on the information whether to perform the position detection using the imaging portion 65.

This is because the undiced wafer W needs application of the adhesive to the entire surface thereof and does not require high accuracy in alignment. The alignment by the alignment section 4 is sufficient for the undiced wafer W. On the other hand, as for the pre-diced wafer W, the adhesive is applied to only application surfaces of the chips so as not to be applied to cut lines L in some cases. In such a case, higher accuracy in alignment is required than the accuracy in alignment by the alignment section 4.

The application section 6 blows gas onto the application surface of the wafer W on the stage 6a moving in the X-axis direction through the nozzle 91 of the cleaning unit 6f to clean the application surface and further sucks the scattered foreign substances through the suction portion 96 of the cleaning unit 6f. Subsequently, the application section 6 causes the application heads 6c to discharge the adhesive through the nozzles when the wafer W on the stage 6a moving in the X-axis direction passes under the application heads 6c to apply the adhesive to the application surface of the wafer W. After the application, the application section 6 moves the stage 6a to the standby position in the X-axis direction by the movement driving portion 53.

The application of the adhesive is performed so that the adhesive is applied to the entire application surface of the wafer W (solid coating) or so that the adhesive is applied to a predetermined region of each chip based on the coating pattern. When the current wafer W is undiced, the application is performed using the pattern of solid coating previously stored in the storage of the controller 8. When the current wafer W is pre-diced, the application is performed using the coating pattern of the adhesive for each chip which is previously stored in the storage of the controller 8 together with the positional information of the chip. The controller 8 controls discharge of the adhesive from the nozzles of each application head 6c based on the information stored in the storage.

During the application, the wafer W is heated by the heating stage 51 of the stage 6a to a desired temperature, thus accelerating drying of the adhesive applied to the application surface of the wafer W. The adhesive on the wafer W acceleratedly dries and drastically decreases in fluidity. In the case where the adhesive at room temperature is applied to the application surface of the wafer W, it is possible to prevent that the adhesive applied in an amount necessary for forming an adhesive film with a desired thickness flows during a slow drying process to cause uneven thickness and prevent liquid flow that the adhesive unevenly flows due to changes in speed or centrifugal force caused in the wafer W while the wafer W coated with the adhesive is transported to the drying section 7.

The application of the adhesive to the wafer W is completed by passing the wafer W under the application heads 6c one time in some cases or by reciprocating the wafer W or passing the wafer W three or more times to further apply the adhesive onto the already applied adhesive in other cases. In the case of repeatedly applying the adhesive, by heating the wafer W to accelerate the drying of the adhesive applied to the application surface of the wafer W, the fluidity of the adhesive previously applied is reduced until the adhesive is applied again. Accordingly, there is an advantage in preventing wetting and spreading of the adhesive and laminating the adhesive properly.

Next, the wafer W is transported from the application section 6 to the drying section 7 by the transport section 3 (step S7). The transport section 3 causes the arm 3b at the transfer position to extend in the direction indicated by the arrow A2 of FIG. 1 and receives the wafer W with the hand 3a from the stage 6a positioned at the standby position in the application section 6. At this time, the stage 6a releases suction of the wafer W and is on standby with the lift pins 51b raised. The transport section 3 inserts the hand 3a in between the stage 6a and the wafer W and picks up the wafer W from underneath to suck and hold the same. Furthermore, the transport section 3 causes the arm 3b to contract and rotate in the θ direction to position the hand 3a at the position for transfer to the drying section 7. The position for transfer to the drying section 7 is the same as the position for transfer to the alignment section 4. The water W is then placed on an available one of the heater plates 101 in the drying section 7. For example, when all the five heater plates 101 are available, the wafers W are sequentially placed starting from the heater plate 101 at the top toward the heater plate 101 at the bottom.

To transfer the wafer W to the heater plate 101, first, the arm 3b is moved up so as to position the hand 3a to the height position corresponding to the heater plate 101 on which the wafer W is to be placed. After the arm 3b is extended in the direction indicated by the arrow A1 of FIG. 1 to insert the hand 3a over the heater plate 101, the arm 3b is moved down. On the other hand, the heater plate 101 is on standby with the lift pins 101b raised, and when the hand 3a moves down, the wafer W on the hand 3a is transferred onto the lift pins 101b. The suction of the wafer W by the hand 3a is released until the wafer W comes into contact with the lift pins 101b after the arm 3b starts to move down. When the arm 3b is contracted to retract the hand 3a from above the heater plate 101, the lift pins 101b move down to place the wafer W on the heater plate 101. The wafer W is then sucked and held by the suction force by the suction holes 101e of the heater plate 101. The retracted hand 3a returns to the transfer position and is on standby for the subsequent action. At this time, since it takes longer time for the drying section 7 to perform the drying operation than the operations carried out by the alignment section 4, the irradiation section 5, and the application section 6, the transport section 3 may be driven to perform the operations of supplying, alignment, UV irradiation, and application operations for the next wafer W during a predetermined time for the drying section 7 to dry the wafer W.

Next, drying is performed by the drying section 7 (step S8). When the wafer W is placed on one of the heater plates 101 by the hand 3a, the drying section 7 heats the wafer W on the heater plate 101. The wafer W is heated for a predetermined drying time, and the adhesive applied on the wafer W is dried. Since the heater plates 101 of the drying section 7 are layered in multiple stages, the drying section 7 is capable of storing the same number of wafers W as the number of stages of the drying section 7. The heater plates 101 may be always heated to the setting temperature by the heater 101a or may be heated each time the wafers W are supplied. At this time, since it takes a certain level of time for a heater plate 101 once cooled down to be heated to the setting temperature, the heater plate 101 on which the wafer W is to be placed should start to be heated during the application operation by the application section 6, for example.

Eventually, the wafer W is transported from the drying section 7 to one of the accommodation sections 2 by the transport section 3 (step S9). The transport section 3 moves up the arm 3b to the height position of the heater plate 101 on which the wafer W to be delivered at the transfer position is placed. The transport 3 then extends the arm 3b and receives the wafer W with the hand 3a. At this time, the heater plate 101 releases suction of the wafer W and is on standby with the lift pins 101b raised. The hand 3a is then inserted between the heater plate 101 and the wafer W and picks up the wafer W from underneath to suck and hold the same. The transport section 3 then causes the arm 3b to perform contraction to return the hand 3a to the transfer position while moving the arm 3b in the X-axis direction and rotating the same in the θ direction, thus positioning the wafer W to the position for transfer to the accommodation section 2. Subsequently, the transport section 3 operates the arm 3b and uses the hand 3a to transfer the wafer W to the accommodation section 2 for export. Specifically, among the support plates 2a of the accommodation section 2, the support plate 2a accommodating the wafer W with the application of the adhesive currently finished is vacant. Accordingly, the transport section 3 moves up and down and contracts the arm 3b so as to return the wafer W with the application finished to the vacant support plate 2a.

By such an operation, the application of the adhesive to one wafer W is completed. The aforementioned operation is repeatedly performed until the application of the adhesive is finished for all the wafers W accommodated in the accommodation section 2.

In the manufacturing process, the discharge stabilizing operation is performed regularly (each application or each predetermined time) or at each specified time while the application is not performed. In the discharge stabilizing operation, the discharge checking operation is performed by the discharge checking portion 81; the wet wiping operation is performed by the cleaning moisturizing portion 82; and the discharge amount checking operation is performed by the discharge amount checking portion 83.

In a state where the stage 6a is positioned at the standby position, the discharge checking portion 81 moves the receiver portion 81d to the reception position, turns on the illumination portion 81c, and then taking images of droplets discharged from the application head 6c corresponding to each of the imaging portions 81a. Subsequently, the discharge checking portion 81 performs image processing for the taken images and compares each taken image with the normal image in terms of the presence, straightness, and shape of droplets and the like to check the discharge state through the nozzles of each of the application heads 6c. After the checking, the discharge checking portion 81 turns off the illumination portion 81 and moves the receiver portion 81d to the retracted position. In such a manner, the discharge state through the nozzles of each of the application heads 6c is checked, and if the discharge state includes any problem, maintenance is performed. It is therefore possible to prevent failure of application of the adhesive due to abnormal discharge.

The cleaning moisturizing portion 82 moves the vessel 82a from the standby position through the wiping position to the original standby position by the movement driving portion 82d to wipe the discharge surface of each of the application heads 6c by the corresponding wiping member 82b within the vessel 82a. Each of the wiping members 82b is moisturized by the solvent supplied through the nozzle 82c. It is therefore possible to wipe out the adhesive sticking to the discharge surfaces of the application heads 6c while moisturizing the discharge surfaces with the adhesive wiped out. Accordingly, the adhesive which cannot be wiped out and remains on the discharge surfaces of the application heads 6c or the adhesive newly sticking to the discharge surface due to later discharge through the nozzles of the application heads 6c can be prevented from drying into condensed solid. It is therefore possible to prevent abnormal discharge such as curved discharge due to the condensate of the adhesive sticking to around the nozzles in the discharge surfaces. The adhesive within the nozzle 82c can be prevented from drying and increasing in viscosity until the start of next discharge after the wiping is completed. It can be therefore prevented that the adhesive is not discharged because of increased viscosity, thus preventing occurrence of failure in application of the adhesive due to abnormal discharge.

The discharge amount checking portion 83 moves the electronic balance 83b to the measuring position in the Y-axis direction, positions the measurement vessel 83c under the application heads 6c, and opens the shutter S. After droplets are discharged from all the nozzles of each of the application heads 6c for a setting number of times, the discharge amount checking portion 83 sequentially calculates the total amount of all the droplets discharged from each of the application heads 6c based on the difference between the outputs of the electronic balance 83b before and after the discharge. After the measurement, the discharge amount checking portion 83 closes the shutter S and moves the electronic balance 83b to the standby position in the Y-axis direction. The amount of discharged droplets is thus checked, and if the amount of discharged droplets includes a problem, maintenance (cleaning of the discharge surfaces of the application heads 6c, adjustment of the discharge amounts from the nozzles of the application heads 6c, and the like) is performed. It is therefore possible to prevent occurrence of failure of the discharge amount.

As described above, the semiconductor device manufacturing apparatus 1 according to the embodiment of the present invention includes: the irradiation section 5 irradiating the wafer W moved by the transport section 3 with ultraviolet light; the application section 6 discharging the adhesive through the application heads 6c toward the wafer W on the stage 6a for coating; and the drying section 7 drying the adhesive applied to the wafer W with heat. With such a configuration, the application surface of the wafer W is subjected to surface modification by the irradiation section 5, and the adhesive is discharged and applied to the application surface with the application heads 6c. The adhesive on the application surface is dried with heat by the drying section 7. The surface modification improves the adherence between the application surface of the wafer W and the adhesive and the leveling property of the adhesive (uniform wet spreadability). Furthermore, the application of the adhesive by the application heads 6c and the drying by the drying section 7 make it possible to uniformly form a film of the adhesive with a desired thickness on the application surface of the wafer W without using an adhesive sheet conventionally used. Even in the case of using an adhesive, it is prevented that void is formed between the coating film of the adhesive formed on a chip and the circuit substrate or the like when the chip singulated by dicing the wafer W is mounted on the circuit substrate, another chip, or the like, thus increasing the reliability in bonding property between the chip and the circuit substrate or the like. Moreover, the adhesive is applied only to an area where the adhesive film to be formed on the wafer W. It is therefore possible to achieve reduction in material cost of the adhesive and an increase in material use efficiency compared to the case of using adhesive sheet requiring a larger area that the wafer W and moreover manufacture high quality semiconductor devices.

Moreover, the wafer W with the adhesive film formed thereon is singulated into chips, and the singulated chips are bonded to the mounting surface of a mounting object with the adhesive film interposed therebetween. At this time, a film with a desired thickness is uniformly formed on the flat mounting surface of each chip as described above. Accordingly, the adhesive film of each chip can be brought into contact with the flat mounting surface of the mounting object without forming void. This can prevent the problem that bubbles within the void swell to press up and damage the chip when the semi-cured adhesive layer is heated to be cured after the chip is bonded to the mounting surface of the mounting target.

Furthermore, gas is blown onto the application surface of the wafer W placed on the stage 6a to clean the application surface, and the foreign substances scattered from the application surface by cleaning are sucked. This can prevent foreign substances from being on the application surface of the wafer W and prevent the foreign substances removed by the blown gas from sticking again. The application quality of the wafer W can be therefore improved, thus manufacturing high quality semiconductor devices. This can prevent foreign substances from being mixed in the coating film of the adhesive formed on the wafer W. Accordingly, it is possible to prevent occurrence of electrical faults such as insufficient insulation and mechanical faults such as cracks and chips due to foreign substances included between the chip singulated by dicing the wafer W and a circuit substrate or another chip to be bonded thereto.

The irradiation section 5 includes: the lamp 5a generating ultraviolet light; the sensor 5c as a detector detecting the amount of ultraviolet light generated by the lamp 5a; an adjustment unit performing adjustment based on the amount of ultraviolet light detected by the sensor 5c so that the amount of light irradiating the application surface of the wafer W is maintained at a setting value (for example, the lamp movement driving portion 5b). With such a configuration, the amount of UV light irradiating the wafer W by the irradiation section 5 is maintained at a setting value and is prevented from fluctuating. The surface modification for the rear surface (application surface) of the wafer W can be reliably and stably performed. It is therefore possible to improve the application quality of the wafer W and thus reliably manufacture high quality semiconductor devices.

In the case of using the lamp movement driving unit 5b adjusting the distance between the lamp 5a and the wafer W as the adjustment unit, the amount of irradiating light can be adjusted with a simple configuration, and the adjustment can be controlled easily and accurately.

The drying section 7 is composed of the plurality of heater plates 101 incorporating the heaters 101a. The heater plates 101 are layered at intervals in multiple stages. With such a configuration, the same number of wafers W as the number of stages can be dried in parallel in a smaller space. It is therefore possible to prevent the apparatus from increasing in size and shorten the manufacturing time at mass production.

Furthermore, the alignment section 4, which has a height smaller than that of the accommodation sections 2, the irradiation section 5, the application section 6, and the drying section 7, is provided on the drying section 7. Accordingly, space to solely locate the alignment section 4 can be eliminated, thus achieving space saving.

Furthermore, the pre-alignment unit 4b is configured so that the holding portion 41 holds the wafer W on the bottom surface thereof and the imaging portion 43 takes images of the peripheral part of the wafer W protruded from the outer circumference of the holding portion 41 from above and is provided above the centering section 4a. Accordingly, there is no need to individually provide spaces to locate the centering unit 4a and pre-alignment unit 4b in the horizontal direction, thus also leading to saving of the installation area. Moreover, the distance that the wafer W is transported from the centering unit 4a to the pre-alignment unit 4b can be made extremely shorter than that in the case where the wafer W is horizontally transported. It is therefore possible to shorten the transport time and increase the productivity.

Furthermore, the centering unit 4a includes: the support table 31 supporting the wafer W; and the plurality of pressing portions 32 pressing and moving the wafer W on the support table 31 from the periphery toward the center in the in-plane direction to align the center of the wafer W with the center of the hand 3a positioned with respect to the support table 31. With such a configuration, the wafer W is pressed at the edge by the pressing portions 32 and moved in the in-plane direction with respect to the hand 3a positioned to the support table 31. Accordingly, the position of the wafer W with respect to the hand 3a can be finely adjusted. The center of the wafer W can be therefore accurately positioned at the center of the hand 3a positioned with respect to the support table 31. Accordingly, the wafer W can be accurately supplied to the application section 6, and the application of the adhesive to the wafer W by the application section 6 can be accurately performed. It is therefore possible to improve the quality of the adhesive film formed on the wafer W.

Furthermore, in each of the pressing portions 32, the pin provided for each of the levers 32a is stopped at the stop position so as to form small gap between the pin and the outer edge of the wafer W. With such a configuration, the wafer W will not be held with the pins of the three pressing portions 32 in contact with the outer edge of the wafer W at the same time. Accordingly, it is prevented that the outer edge of the wafer W is damaged by the pins of the three pressing portions 32 simultaneously pressed against the outer edge of the wafer W during positioning by the pressing portions 32 and that the wafer W is held and curved. This prevents misalignment of the wafer W due to restoration of the curved wafer W when the pressing portions 32 are retracted. It is therefore possible to perform accurate positioning of even the wafer W composed of a thin sheet such as a semiconductor wafer.

Furthermore, the hand 3a includes the plurality of comb teeth-shaped support portions 3a1 supporting the wafer W, and the support table 31 includes the plurality of comb teeth-shaped support portions 31a to support the wafer W. The support portions 31a of the support table 31 form a shape capable of being interdigitated with the support portions 3a1 of the hand 3a. The wafer W is supported at a plurality of places on the support portions 3a1 of the hand 3a or the support portions of the support table 31 (seven places on the hand 3a and seven places on the support table 31). With such a configuration, the intervals at which the support portions 3a1 and 31a support the wafer W can be minimized. Accordingly, the wafer W is equally supported at many places on both the support table 31 and the hand 3a. It is possible to prevent deflection of the wafer W under the wafer's own weight, thus preventing the misalignment due to the deflection of the wafer W. Accordingly, accurate positioning can be performed with a simple configuration.

Furthermore, the apparatus 1 includes the controller 8 as an adjustment unit adjusting the amounts by which the wafer W is pressed by the pressing portions 32. With such a configuration, the pressing amounts of the plurality of pressing portions 32 are adjusted by the controller 8. The wafer W on the hand 3a interdigiated with the support table 31 is moved by the pressing portions 32 in the in-plane direction and to cause the center of the wafer W to be aligned with the center of the hand 3a positioned with respect to the support table 31. It is therefore possible to easily perform accurate positioning.

The pre-alignment unit 4b includes: the holding portion 41 holding the wafer W; the rotation driving portion 42 rotating the holding portion 41 in a plane extending along the held surface of the wafer W; the imaging portion 43 taking images of the peripheral part of the wafer W held by the holding portion 41; and the image processing computing unit processing the images taken by the imaging portion 43 and calculating the tilt (direction) of the rotational direction of the wafer W. With such a configuration, images of the peripheral part of the wafer W are taken without damaging the wafer W and are used for alignment. Accordingly, the position of the wafer W can be finely adjusted. It is therefore possible to perform accurate positioning even in the case of using the wafer W composed of a thin sheet such as a semiconductor wafer.

Furthermore, the image processing computing unit calculates the amount of correction for positioning the wafer W with respect to the stage 6a to the predetermined position based on the images taken by the imaging portion 43. The amount of correction is used for positioning, and it is therefore possible to easily perform accurate positioning.

Furthermore, the apparatus 1 includes: the controller 8 controlling the alignment section 4; and the storage storing information concerning the necessity for positioning of the wafer W by the alignment section 4. The controller 8 determines based on the information stored in the storage whether to perform positioning of the wafer W by the alignment section 4. With such a configuration, it is prevented that a wafer W not requiring high positioning accuracy (for example, an undiced wafer W) is subjected to positioning by the alignment section 4, thus shortening the manufacturing time. The productivity can be increased.

The holding portion 41 of the pre-alignment unit 4b sucks and receives the upper surface of the wafer W held on the hand 3a onto the bottom surface thereof from above, and the imaging portion 43 placed above the holding portion 41 takes images of the peripheral part of the wafer W. With such a configuration, the operation from the transfer of the wafer W to the image shooting can be smoothly performed, thus shortening the time taken to perform pre-alignment. The productivity can be therefore shortened. The productivity can be increased.

The holding portion 41 is configured to be arranged with only the peripheral part of the wafer W (the region where the notch N is formed) protruded from the outer circumference. The protruding part is very small compared with the region of the wafer W held by the holding portion. This prevents the protruding part (peripheral part) from sagging under the wafer's own weight as much as possible even in the case where the wafer W is thin. Accordingly, it can be prevented that the accuracy in detecting the position of the notch N is reduced by the deflection of the peripheral part. It is therefore possible to perform accurate positioning.

Furthermore, the wafer W aligned by the centering unit 4a and pre-alignment unit 4b is supplied to the stage 6a of the application section 6. Accordingly, the wafer W can be supplied to the stage 6a accurately. In the case of performing position detection for the wafer W using the imaging portion 65 on the stage 6a, the image shooting targets in the chips on the wafer W, such as corners to be imaged, can be reliably caught in the field of view. This can prevent detection error due to supply of the wafer W with the image shooting target out of the field of view, and the position of the wafer W can be detected efficiently. This can also increase the productivity.

Furthermore, each of the accommodation sections 2 includes the support plate 2a having the plurality of support portions 2a1 supporting the wafer W in a form of comb teeth, and the hand 3a includes the plurality of support portions 31a supporting the wafer W in a form of comb teeth. The support portions 31a of the hand 3a have the shapes interdigitated with the support portions 2a1 of the accommodation section 2. With such a configuration, at exchanging the wafer W between the accommodation section 2 and the hand 3a, the supporting portions 3a1 of the hand 3a are interdigitated with the supporting portions 2a1 of the support plate 2a to receive the wafer W from the support plate 2a or transfer the wafer W onto the support plate 2a. This eliminates the need for the plurality of pins which are capable of moving up and down for exchange the wafer W like the conventional one. Moreover, the wafer W is supported at a plurality of places (seven on the support plate 2, and six on the hand 3a) on the support portions 2a1 of each support plate 2 and the support portions 3a1 of the hand 3a. The intervals at which the support portions 3a1 and 31a support the wafer W can be therefore minimized. This can prevent the wafer W from being deformed at exchange, thus implementing reliable exchange. It is therefore possible to stably exchange a thin sheet-shaped wafer W such as a semiconductor wafer using such as a robot hand.

Furthermore, the support plate 2a includes the plurality of hold pins 11 restricting the movement of the supported wafer W in the in-plane direction, and the hand 3a includes the plurality of hold pins 21 restricting the movement of the supported wafer W in the in-plane direction and the plurality of suction holes 22 through which the supported wafer W is sucked and fixed to the hand 3a. Accordingly, the movement of the wafer W in the in-plane direction is restricted by the hold pins 11 of the support plate 2a and the hold pins 21 of the hand 3a at exchanging the wafer W. Moreover, the wafer W is sucked and fixed through the suction holes 22 of the hand 3a, thus achieving more reliable exchange.

Furthermore, each of the accommodation sections 2 includes the reinforcement member 12 reinforcing the support portions 2a1 of each of the support plates 2a. The reinforcement member 12 is provided under the support portions 2a1 of the support plate 2a across the direction that the support portions 2a1 extend so as to support the support portions 2a1 of the support plate 2a. The individual support portions 2a1 of each of the support plates 2a are reinforced by one member. Accordingly, the wafer W can be supported without being deformed even when the support plates 2a are made thinner or the support portions 2a1 of the support plates 2a are extended thinner and longer, thus implementing reliable exchange. The support plates 2a are made thinner for the purposes of increasing the number of wafers W accommodated in the accommodation section 2 by increasing the number of the support plates 2a without increasing the accommodation section 2 in size.

Furthermore, the drying section 7 includes: the plurality of heater plates 101 each of which allows the wafer W coated with the adhesive to be placed thereon and heats the placed wafer W; and the support portions 102 supporting the heater plates 101 layered at intervals. After the adhesive is applied by the application heads 6c, pre-drying by the drying section 7 is performed. This can prevent that the liquid adhesive applied on the wafer W flows and unevenly spreads during the transport of the wafer W to a curing apparatus at the later process to provide uneven film thickness. The drying unevenness of the adhesive can be therefore reduced. Accordingly, even in the case of using a liquid-type adhesive, the thickness of the coating film of the adhesive can be made uniform. This makes it possible to use a liquid-type adhesive instead of the adhesive sheet. It is therefore possible to achieve reduction in material cost of the adhesive and an increase in material use efficiency compared with the case of using the adhesive sheet. Moreover, the problems due to peel off or roll up of the adhesive sheet can be avoided, so that high quality semiconductor devices can be manufactured. Moreover, the drying section 7 is capable of drying the same number of wafers W as the stages of the drying section 7 at one time at smaller space. It is possible to prevent the apparatus from increasing in size while shortening the manufacturing time at mass production.

Furthermore, in the drying section 7, each of the heater plates 10 is provided with the switching unit switching between the contact state in which the wafer W is in contact with the heater plate 101 and the separate state in which the wafer W and the heater plate 101 are separated at a predetermined distance. The wafer W is therefore heated in any one of the contact state and the separate state, thus allowing the drying conditions to be changed according to the adhesive material, ambient temperature, and the like. This can reduce the drying unevenness of the adhesive throughout the wafers W due to differences of stages on which the wafers W are placed. It is therefore possible to make the thickness of the coating film of the adhesive surely uniform.

Furthermore, the switching unit includes the plurality of lift pins 101b moving up and down the wafer W placed on each of the heater plates 101, and the drying section 7 includes the temperature measuring equipment T measuring the temperature of the heater plate 101. The stop positions of the lift pins are changed according to the temperature measured by the temperature measuring equipment T, thus adjusting the distance between the heater plate 101 and the wafer W. It is therefore possible to control the amount of heat given to the wafer W more quickly than control of the temperature of the heater plate 101. This can prevent the wafer W from being heated excessively or insufficiently and therefore steadily reduce the drying unevenness of the adhesive on the wafers W. It is therefore possible to more reliably provide coating film of the adhesive with uniform thickness.

Furthermore, the apparatus 1 includes the irradiation section 5 irradiating the application surface of the wafer W with ultraviolet light, and the application section 6 applying the adhesive to the application surface irradiated by the ultraviolet light. The application surface of the wafer W is therefore modified so that the adhesive stably adheres to the application surface of the wafer W. This increases the adherence between the application surface of the wafer W and the adhesive. This allows use of a liquid-type adhesive, therefore reducing the material cost of the adhesive and increasing the material use efficiency compared to the case of using an adhesive sheet. Furthermore, the adhesive sheet is unnecessary, and the increased adherence can prevent the coating film of the adhesive from peeling off or rolling up together with dicing tape when the dicing tape is peeled off. It is therefore possible to increase the reliability of bonding between each chip singulated by dicing the wafer W and a circuit board or another chip to be bonded and manufacture high quality semiconductor devices.

Furthermore, the apparatus 1 includes: the hand 3a supporting the wafer W and the transport section 3 transporting the wafer W with the hand 3a; and the irradiation section 5 irradiates with ultraviolet light the application surface of the wafer W being moved by the transport section 3. Accordingly, the integrated amount of light for the surface modification can be adjusted by the operation of the hand 3a. For example, the hand 3a reciprocates the wafer W under the lamp 5a of the irradiation section 5. The wafer W therefore passes under the lamp 5a totally twice. By passing twice, it is possible to ensure the predetermined integrated amount of light per unit area necessary for surface modification. The application surface of the wafer W can be therefore reliably modified, and the adhesive can stably adhere to the application surface of the wafer W. This can increase the application quality of the wafer W and manufacture high quality semiconductor devices.

Furthermore, the irradiation section 5 includes: the lamp 5a generating ultraviolet light; the sensor 5c as a detector detecting the amount of ultraviolet light generated by the lamp 5a; the adjustment unit performing adjustment based on the amount of ultraviolet light detected by the sensor 5c so that the amount of light irradiating the application surface of the wafer W is maintained at a setting value (for example, the lamp movement driving portion 5b). Accordingly, the amount of UV light irradiating the wafer W with the irradiation section 5 is maintained at a setting value and is prevented from fluctuating. The surface modification for the rear surface (application surface) of the wafer W can be reliably and stably performed. It is therefore possible to improve the application quality of the wafer W and thus reliably manufacture high quality semiconductor devices.

In the case of using the lamp movement driving unit 5b adjusting the distance between the lamp 5a and the wafer W as the adjustment unit, the amount of irradiating light can be adjusted with a simple configuration, and the adjustment can be controlled easily and accurately.

The apparatus 1 includes: the stage 6a which allows the wafer W to be placed thereon and heats the placed wafer W; and the application head 6c discharging the plurality of droplets of the adhesive toward the application region of the placed wafer W heated by the stage 6a. The droplets sticking to the wafer W are sequentially dried by heat supplied from the stage 6a and are therefore uniformly dried. Even in the case of using a liquid-type adhesive, it is possible to prevent the adhesive flow that the liquid adhesive not dried yet unevenly flows on the wafer W during the transport of the wafer W to a drying machine and the like and form coating film of the adhesive to a desired uniform thickness. This makes it possible to use a liquid-type adhesive instead of the adhesive sheet, thus reducing the material cost of the adhesive and increasing the material use efficiency compared with the case of using the adhesive sheet. Moreover, the problems due to peeling off or rolling up of the adhesive sheet can be avoided, thus making it possible to manufacture high quality semiconductor devices. Moreover, the heating temperature is set to such a temperature that can prevent the adhesive from flowing, for example, such a temperature that promotes vaporization of the solvent contained in the adhesive, for example.

Moreover, the stage 6a includes the heating stage 51 having the plurality of suction holes 51e for sucking the placed wafer W, and the placed wafer W is brought into close contact with the heating stage 51 by suction due to the suction holes 51e to be heated. Accordingly, the droplets of the adhesive rapidly increase in viscosity after sticking to the wafer W and are surely prevented from flowing. This prevents the plurality of droplets of the adhesive sticking to each other to be integrated on the wafer W from being wet spreading. It is therefore possible to form the coating film of the adhesive to a desired thickness and surly achieve uniform film thickness.

Furthermore, the apparatus 1 includes: the application heads 6c discharging the plurality of droplets of the adhesive to the wafer W; the stage 6a which allows the wafer W to be placed thereon and is movable under the application heads 6c; and the discharge stabilizing unit 6e stabilizing discharge of the application heads 6c. The discharge stabilizing unit 6e includes: the discharge checking portion 81 taking images of the droplets discharged from the application heads 6c for discharge check; the cleaning moisturizing portion 82 cleaning and moisturizing the discharge surface of each of the application heads 6c; and the discharge amount checking portion 83 checking the total amount of adhesive discharged from each of the application heads 6c. By the discharge checking portion 82, the state of each of the application heads 6c is checked, and if there is any problem with the state, the maintenance is performed, thus preventing occurrence of abnormal discharge. The cleaning moisturizing portion 82 prevents the adhesive sticking to the discharge surfaces of the application heads 6c from drying into condensed solid, thus preventing the occurrence of abnormal discharge such as curved discharge. The discharge amount checking portion 83 checks the amount of discharged droplets, and if there is any problem with the amount of discharged droplets, the maintenance is performed, thus preventing the occurrence of abnormal discharge amount. Accordingly, it is possible to implement stable application of liquid-type adhesive, thus allowing use of a liquid-type adhesive instead of the adhesive sheet. It is therefore possible to reduce the material cost of the adhesive and increase the material use efficiency compared with the case of using the adhesive sheet. At application of the adhesive on the wafer W, discharge failure that the adhesive is not discharged from the nozzle of the application head 6 is prevented, thus ensuring that the droplets of the adhesive are applied to a region on the wafer W to which the adhesive is to be applied. It is therefore possible to manufacture high quality semiconductor devices.

The discharge checking portion 81 includes: the plurality of imaging portions 81a provided so as to take images of the droplets discharged from the application heads 6c; the up and down movement driving portion 81b moving up and down the imaging portions 81a between the retracted position and the shooting position (operation position); the illumination portion 81c for image shooting; the receiver portion 81d receiving droplets discharged from the application heads 6c; and the up and down movement driving portion 81e moving up and down the illumination portion 81c and receiver portion 81d. The cleaning moisturizing portion 82 includes: the box-shaped vessel 82a open at the top; the wiping members 82b provided within the vessel 82a; the nozzles 82c spraying the solvent to the wiping members 82b; and the movement driving portion 82d moving the vessel 82a up and down and in the direction along the discharge surface. The discharge amount checking portion 83 includes: the box-shaped casing 83a provided with the shutter S openable and closable; the electronic balance 83b for measurement; the measuring vessel 83c provided on the electronic balance 83b; the shutter driving portion 83d opening and closing the shutter S; and the movement driving portion 83e moving the casing 83a in the direction along the discharge surfaces. With such a configuration, the application operation and the discharge stabilizing operation can be easily switched by moving the aforementioned portions. Moreover, the discharged droplets and sprayed solvent are collected to prevent contamination of the apparatus. Since the discharge amount is measured within the casing 83a without air flows or the like, the measurement is performed at high accuracy. This allows reliable maintenance, thus more reliably implementing stable application of the liquid-type adhesive.

The discharge checking portion 81 includes: the up and down movement driving portion 81b moving up and down the imaging portion 81a between the retracted position and the shooting position (operation position); and the up and down movement driving portion 81e moving up and down the illumination portion 81c and receiver portion 81d between the retracted positions and the operation positions. The imaging portion 81a is retracted by the up and down movement driving portion 81b to the retracted position set above the moving region of the stage 6a. The illumination portion 81c and the receiver portion 81d are retracted by the up and down movement driving portion 81e to the retracted positions set below the moving region of the stage 6a. By retracting the imaging portion 81a to above the moving region of the stage 6a, it is prevented that dust which is generated and falls due to movement of the stage 6a, mist which is generated and falls when the droplets of the adhesive are discharged from the nozzles of the application heads 6c, and the like from sticking to the lens of the imaging portion 81 and the like. This can enhance the reliability in discharge checking. Moreover, by retracting the receiver portion 81d below the moving region of the stage 6a, even if the adhesive received by the receiver portion 81d spills out from the receiver portion 81d, the spilled adhesive can be prevented from falling onto the wafer W being moved by the stage 6a. This can increase the quality of the adhesive film formed on the application surface of the wafer W. By individually retracting the imaging portion 81a and the receiver portion 81d to the different retracted positions in such a manner, it is possible to enhance the reliability of discharge checking while increasing the quality of the adhesive film formed on the application surface of the wafer W.

The cleaning moisturizing unit 82 includes the movement driving portion 82d moving the wiping member 82b together with the vessel 82a up and down and in the X-axis direction to the retracted and operation positions. The wiping member 82b is retracted by the up and down movement driving portion 82e to the retracted position set below the moving region of the stage 6a. With such a configuration, the stage 6a is located between the wiping member 82b and the wafer W. Accordingly, even if the adhesive sticking to the wiping member 82b falls when the discharge surfaces of the application heads 6c are wiped, the adhesive falling from the wiping member 82b is surely prevented from sticking to the wafer W. Furthermore, it is possible to prevent formation failure or degradation in quality of the adhesive layer on the wafer W due to adhesive other than the adhesive discharged from the nozzle of the application heads 6c to stick to the wafer W.

Furthermore the discharge amount checking portion 83 includes the movement driving portion 83e moving in the Y-axis direction to move the electronic balance 83b for measurement to the retracted position and the operation position. The electronic balance 83b is retracted by the movement driving portion 83e to the retracted position on the side of the moving region of the stage 6a. With such a configuration, the moving direction that the electronic balance 83b moves through the plurality of application heads 6c for checking the discharge amount can be aligned with the moving direction that the electronic balance 83b moves to the retracted position. Accordingly, there is no need to provide a special moving mechanism to retract the electronic balance, thus simplifying the apparatus configuration. Moreover, the electronic balance between the retracted position and the operation position is moved only in the Y-axis direction along the horizontal direction. Accordingly, the electronic balance is prevented from tilting while moving. It is therefore possible to minimize degradation of the measurement accuracy due to tilting of the electronic balance with respect to the horizontal direction and implement accurate checking of the discharge amount.

The retracted positions of the receiver portion 81d of the discharge checking portion 81 and each of the wiping members 82b of the cleaning moisturizing portion 82 are set side by side in the X-axis direction, which is the moving direction of the stage 6a, below the moving region of the stage 6a. Specifically, the retracted position of the receiver portion 81d is set directly under the application heads 6c, and the retracted position of the wiping members 82c is set adjacent to the retracted position of the receiver portion 81d on the transport section 3 side. Accordingly, the difference in height between the receiver portion 81d and the wiping members 82b positioned at the retracted positions can be minimized, and therefore the heights of the space where the receiver portion 81d and the wiping members 82b are retracted can be minimized below the moving region of the stage 6a. The apparatus 1 can be made small, and the height at which the stage 6a moves can be prevented from increasing. Accordingly, the height of the wafer W being transported in the apparatus 1 can be set low as a whole, and the sections 2 to 7 are easily accessible by operator's hands, thus improving the maintenance performance of the entire apparatus.

The imaging portion 81a of the discharge checking portion 81, the illumination portion 81c, the receiver portion 81d, and the wiping members 82b of the cleaning moisturizing portion 82, all of which have lengths approximately equal to the length of the array of the plurality of application heads 6c in the Y-axis direction, are retracted in the Z-axis direction. The electronic balance 83b of the discharge amount checking portion 83 having a length in the Y-axis direction shorter than the length of the array of the plurality of application heads 6c in the Y-axis direction is retracted in the Y-axis direction. Moreover, the imaging portion 81a of the discharge checking portion 81 is retracted upward in the Z-axis direction, and the illumination portion 81c and the receiver portion 81d are retracted downward in the Z-axis direction. Furthermore, the illumination portion 81c and receiver portion 81d of the discharge checking portion 81 and the wiping member 82b of the cleaning moisturizing portion 82 are retracted both downward in the Z-axis direction and are arranged side by side in the X-axis direction when being located at the retracted positions. With such a configuration, only the electronic balance 83b having a comparatively short length in the Y-axis direction is retracted in the horizontal direction. Accordingly, the space for retraction in the horizontal direction can be minimized. Moreover, since the illumination portion 81c, the receiver portion 81d, and the wiping members 82b, which are retracted downward in the Z-axis direction, are located side by side when being retracted to the retracted positions, the retraction space in the Z-axis direction can be minimized. It is therefore possible to minimize space as the space for retraction within the apparatus, thus miniaturizing the apparatus.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, the aforementioned embodiments describe various numeral values, but such numeral values are examples and not limited.

In the description of the aforementioned embodiments, for example, the drying section 7 is configured to support the wafer W on the heater plate 101 and heat and dry the adhesive applied to the wafer W. However, the drying section 7 is not limited to this. The drying section 7 may be provided with a plate for supporting the wafer W instead of the heater plate 101 and configured to heat and dry the adhesive by supplying warm wind, heat and dry the adhesive by heating the ambient temperature around the wafer W with a heating unit such as a heater, or dry the adhesive under the reduced pressure by reducing pressure of the atmosphere around the wafer W.

In the description of the aforementioned embodiments, the application section 6 is configured to apply the adhesive while moving the application heads 6c in the X-axis direction relative to the wafer W. However, the application section 6 is not limited to this and may be configured to apply the adhesive while rotating the wafer W in a horizontal plane under the plurality of application heads 6c arranged in lines.

In such a case, the adhesive is applied to the wafer W on the stage 6a with the ink jet type application heads 6c while stage 6a with the wafer W placed thereon is being rotated. The application section 6 has a configuration basically same as that of the aforementioned embodiments. However, the application heads 6c are not necessary to be arranged in the range covering the length of the diameter of the wafer W (the number of the application heads 6c is seven in the aforementioned embodiments) and only should be arranged in a range covering from the center to circumference of the wafer W placed on the stage 6a. However, similar to the aforementioned embodiments, the application heads 6c may be arranged in the range covering the length of the diameter of the wafer W.

Herein, in the application operation when the application heads 6c are arranged in the range covering the diameter of the wafer W similar to the aforementioned embodiments, when the wafer W is placed by the hand 3a on the stage 6a located at the standby position, the stage transport driving unit 6b is driven to move the stage 6a in the X-axis direction so that the center of the wafer W is located just under the central application head 6c among the seven application heads 6c arrayed in a line. The stage 6a located at this position is rotated in one direction at a predetermined speed by the rotation driving portion 52 while the adhesive is discharged from the nozzles of each of the application heads 6c for application of the adhesive on the application surface of the wafer W. When the application of the adhesive onto the application surface of the wafer W is completed, the rotation of the stage 6a is stopped at the position of 0 degree (the same as the position when the wafer W is supplied) and then moved by the stage transport driving portion 6b to the standby position. It is preferable that the application of the adhesive to the rotating wafer W is applied to the case of performing solid coating by which the adhesive is applied to the entire application surface of the wafer W uniformly.

In rotating application, the application heads 6c at further distance from the rotational center have higher moving speed relative to the application surface of the wafer W. Accordingly, if the same amount of adhesive is discharged from the nozzles of the seven application heads 6c with a same period, the droplets of the adhesive applied to the application surface are distributed more sparsely at further distance from the rotational center. Accordingly, the discharge of the adhesive is controlled so that the amount of adhesive per unit time is set larger at further distance from the rotational center to uniform the distribution of the droplets of the adhesive on the application surface. For example, the discharge is controlled so that the nozzles at further distance from the rotational center will discharge larger amounts of adhesive or discharge the adhesive with a shorter period.

Especially in the case of arranging the application heads 6 in the range covering the diameter of the wafer W, the application surface of the wafer W is separated at a predetermined distance from the rotational center into two regions: an inside region on the rotational center side and an outside region on the peripheral side. The application of the adhesive to the inside region is performed using half of the nozzles located to the right of the rotational center among the nozzles located facing the inside region. The application of the adhesive to the outside region is performed using all the nozzles located facing the outside region. This allows more adhesive to be applied to the outside region where the relative moving speed of each of the application heads to the application surface is higher than that in the inside region.

Moreover, the application surface of the wafer may be separated into, not limited to two regions, three or more regions in the radial direction. In such a case, the discharge is controlled so that the adhesive is discharged from all the nozzles located in the right side of the rotational center. Moreover, as for the nozzles located in the left side of the rotational center, the number of nozzles in a group of nozzles facing the region further from the rotational center is larger than another group of nozzles closer to the rotational center. For example, in the case where the application surface of the wafer W is divided into three regions, in the nozzles located in the left side of the rotational center, the group of nozzles facing the inside region is configured not to discharge the adhesive. In the group of nozzles facing the middle region, the adhesive is discharged from every other nozzle. In the group of nozzles facing the outside region, the adhesive is discharged from all of the nozzles.

The application heads 6c may be provided so as to horizontally rotate with respect to the holding member 64a and may be horizontally rotated according to the distance from the rotational center. To be specific, the application heads 6c are arranged with the nozzle array extended in the Y-axis direction at distance closer to the rotational center. The application heads 6 may be horizontally rotated and arranged so that the nozzle array intersects the Y-axis direction at larger angle at further distance from the rotational center. This makes the intervals of the arranged nozzles in the Y-axis direction shorter at further distance from the rotational center. Accordingly, the discharged droplets of adhesive in the radial direction get denser toward the circumference. It is therefore possible to prevent the droplets of the adhesive on the application surface from being distributed sparsely on the peripheral side even if the adhesive is discharged from each nozzle at the same discharge amount per unit time.

Moreover, the application of the adhesive by the application section 6, which is described in the step 6 of the aforementioned embodiments, can be performed in the following manner. Specifically, in the case of the pre-diced wafer W or the like, to form an adhesive film for each chip on the wafer W in a pattern of a shape similar to the chip (for example, rectangular shape), the application of the adhesive is separately performed by two steps.

At a first step, the adhesive is applied in one or more lines along the outer edge of a rectangular application region. Specifically, the application is performed so that adjacent droplets of adhesive overlap each other, thus forming a frame of the adhesive. The frame of the adhesive may be formed by one line of droplets or two or more lines of droplets. At this time, the heating stage 51 of the stage 6a is set to a temperature high enough that each droplet of adhesive sticking to the wafer W immediately starts drying in the entire droplet to be prevented from wet spreading. This makes it possible to form a frame of the adhesive with the height kept close to the height of the droplets of adhesive when the droplets stick to the wafer W, or a frame-shaped adhesive layer along the outer edge of the application region.

To form the frame-shaped adhesive layer at the first step, the operation of applying the droplets of adhesive to the outer edge of the application region should be repeatedly performed to overlay the droplets of adhesive several times on the droplets of adhesive which are already applied and start drying. This can provide a height (thickness) necessary for the adhesive layer formed in the application region.

Moreover, the droplets of adhesive are applied so as to overlap each other in the above description. However, the droplets of adhesive may be first applied at predetermined intervals and may be then applied so as to fill the gap between the first droplets.

Next, in a second step, the droplets of adhesive are sequentially applied in a region inside the frame-shaped adhesive layer formed at the first step. At this time, the heating stage 51 of the stage 6a is set to a temperature lower than that of the first step so that the droplets sticking to the wafer W have higher wet spreadabilty than that of the first step. This allows the droplets of adhesive applied at the second step to easily conform to the frame-shaped adhesive layer formed at the first step, thus forming an adhesive layer integrated with the frame-shaped adhesive layer.

In such a case, the shape of the adhesive layer to be formed is limited by the frame-shaped adhesive layer, and the adhesive layer can be prevented from protruding from the application region on each chip. Accordingly, even in the case of applying the adhesive to the pre-diced wafer W and the like, it is prevented that the adhesive is protruded and applied to the dicing grooves, thus preventing failure that adjacent chips are attached to each other with the protruded adhesive. It is therefore possible to prevent defective products due to such failure and increase the productivity.

Also in the case of performing solid coating of the entire surface of the wafer W with the adhesive, similarly to the above description, a frame-shaped adhesive layer may be formed along the outer edge of the application region on the wafer W at the first step, and the adhesive may be applied in the region within the frame-shaped adhesive layer at the second step.

Moreover, the apparatus 1 may be provided with the controller 8 controlling the temperature for heating the wafer W by the stage 6a and the discharge of the adhesive by the application heads 6c. The controller 8 is configured to change the temperature for heating the wafer W according to the application position of the adhesive in the application region on the wafer W. Even in the case where the temperature for heating the wafer W with the stage 6a varies depending on the location in the surface of the stage 6a, therefore, the drying unevenness due to the temperature unevenness can be reduced. This allows the droplets to uniformly dry, thus more reliably forming a coating film of the adhesive with uniform thickness.

The controller 8 may control discharge of the adhesive by the application heads 6c so that the application of the adhesive to the application region on the wafer W is separated into application for the outer edge and application to the inside region. The temperature for heating the wafer W with the stage 6a is set higher at the application of the adhesive to the outer edge than the application of the adhesive to the region inside the outer edge. This makes it possible to form a frame of the adhesive with the height kept close to the height of the droplets of adhesive when the droplets stick to the wafer W, or a frame-shaped adhesive layer along the outer edge of the application region. Accordingly, each droplet of the adhesive sticking to the wafer W immediately starts drying in the entire droplet to be prevented from wet spreading. It is therefore possible to surely form a coating film of the adhesive to a desired uniform thickness.

What is claimed is:

1. A semiconductor device manufacturing apparatus, comprising:
an accommodation section accommodating an application object;
an irradiation section irradiating the application object taken out from the accommodation section with ultraviolet light;
an application section comprising a stage allowing the application object to be placed thereon and an application head discharging a plurality of droplets of an adhesive to the application object placed on the stage, the application section applying the adhesive through the application head to the application object which is irradiated by ultraviolet light through the irradiation section and is placed on the stage;
a drying section drying the adhesive applied on the application object with heat; and
a transport section comprising a hand supporting the application object, the transport section which is capable of transporting the application object accommodated in the accommodation section to the irradiation section, the application section, and the drying section.

2. The semiconductor device manufacturing apparatus according to claim 1, further comprising
an alignment section aligning the application object supported by the hand with the hand.

3. The semiconductor device manufacturing apparatus according to claim 1, further comprising
a cleaning section blowing gas to a surface of the application object placed on the stage to clean the surface of the application object.

4. The semiconductor device manufacturing apparatus according to claim 1, wherein
the irradiation section includes:
a lamp generating the ultraviolet light;
a detector detecting an amount of the ultraviolet light generated by the lamp; and
an adjustment section adjusting and maintaining the amount of light irradiating the application object at a setting value based on the amount of ultraviolet light detected by the detector.

5. The semiconductor device manufacturing apparatus according to claim 4, wherein
the adjustment section is a driving unit adjusting a relative distance between the lamp and the application object.

6. The semiconductor device manufacturing apparatus according to claim 1, wherein
the drying section includes a plurality of heater plates, each of the heater plates incorporating heaters, the drying section composed of the heater plates layered and arranged in multiple stages at intervals.

7. A semiconductor device manufacturing method, comprising:
taking out an application object from an accommodation section configured to accommodate the application object using a transport section configured to transport the application object with a hand supporting the application object;
irradiating the application object with ultraviolet light using an irradiation section configured to project ultraviolet light to the application object taken from the accommodation section with the hand;
transporting the application object irradiated by the ultraviolet light onto the stage using the transport section;
applying adhesive to the application object transported on the stage using an application head configured to discharge a plurality of droplets of the adhesive;
transporting the application object with the adhesive applied thereto to a drying section configured to dry the application object with heat using the transport section; and
drying the adhesive applied to the application object using the drying section.

8. The semiconductor device manufacturing method according to claim 7, further comprising
aligning the application object supported by the hand with the hand before transporting the application object taken from the accommodation section onto the stage.

9. The semiconductor device manufacturing method according to claim 7, further comprising
cleaning a surface to the application object using a cleaning section configured to blow gas toward a surface of the application object placed on the stage before applying the adhesive.

10. The semiconductor device manufacturing method according to claim 7, further comprising
detecting an amount of the ultraviolet light projected by the irradiation section and,
adjusting a relative distance between the irradiation section and the application object to maintain the amount of light irradiating the application object at a setting value based on the detected amount of ultraviolet light.
